(19) United States
(12) Patent Application Publication
(10) Pub. No.: US 2026/0283341 A1
(43) Pub. Date: Sep. 24, 2026

(54) SUBSTRATE PROCESSING DEVICE

(71) Applicant: SCREEN Holdings Co., Ltd., Kyoto (JP)

(72) Inventors: Shotaro TSUDA, Kyoto-shi (JP); Takayuki NISHIDA, Kyoto-shi (JP)

(73) Assignee: SCREEN Holdings Co., Ltd., Kyoto (JP)

(21) Appl. No.: 19/546,453

(22) Filed: Feb. 23, 2026

(30) Foreign Application Priority Data
Mar. 18, 2025 (JP) 2025-044096

(51) Int. Cl. A46B 15/00; A46B 5/00; A46B 13/00; A46B 13/02; H10P 72/00

(52) U.S. Cl. CPC A46B 15/0012; A46B 5/0012; A46B 13/008; A46B 13/02; H10P 72/0412; A46B 2200/3073

(57) ABSTRACT

A substrate processing device includes a plurality of cleaning members arranged in parallel in a radial direction of a substrate and cleaning the substrate; a support member supporting the plurality of cleaning members; a rotary drive part causing the support member to relatively rotate with respect to the substrate; a plurality of connecting members connecting each of the plurality of cleaning members and the support member and each being capable of moving up and down independently; and a pressing force adjustment mechanism causing the plurality of connecting members to move up and down respectively such that each of pressing forces exerted on the substrate by each of the plurality of cleaning members becomes uniform.

### CROSS-REFERENCE TO RELATED APPLICATION

This application claims the priority benefits of Japanese application no. 2025-044096, filed on Mar. 18, 2025. The entirety of the above-mentioned patent application is hereby incorporated by reference herein and made a part of this specification.

### BACKGROUND

### Technical Field

The disclosure relates to a substrate processing device that performs cleaning processing by applying a brush to substrates such as semiconductor wafers, substrates for liquid crystal displays or organic EL (Electroluminescence) display devices, and glass substrates for photomasks (hereinafter simply referred to as “substrates”).

### Related Art

When manufacturing semiconductor components and the like, various processings such as film formation processing or cleaning processing are performed on the surface (circuit formation surface) of a substrate. Here, when performing various processings on the surface of a substrate, contaminants such as particles may adhere to the back surface of the substrate. To avoid adverse effects on the substrate caused by contaminants, substrate processing devices have been proposed that perform cleaning of the back surface of the substrate (lower surface of the substrate) facing downward in addition to cleaning of the substrate surface facing upward.

A conventional substrate processing device includes an upper peripheral edge holding part, a lower holding rotation part, and a lower surface cleaning part (see, for example, Japanese Patent Application Laid-Open Publication No. 2024-106198). The peripheral edge holding part holds the substrate by contacting two portions of the outer peripheral end of the substrate in a horizontal posture and sandwiching the substrate. The holding rotation part includes a suction holding part rotatable around an axis in the Z direction, and uses the suction holding part to suction-hold the center region of the lower surface of the substrate. The holding rotation part and the lower surface cleaning part are movable along the Y direction.

The lower surface cleaning part includes a lower surface brush, a liquid nozzle, and a gas ejection unit. The gas ejection unit ejects nitrogen gas. An ejection port of the gas ejection unit is formed in a slit shape extending in the X direction. Therefore, the gas ejection unit ejects band-shaped nitrogen gas extending in the X direction.

A conventional substrate processing device operates as follows. The diameter of the substrate is assumed to be 300 mm. With the peripheral edge holding part keeping the substrate stationary without rotating it, the center region of the lower surface of the substrate (for example, a region with a radius of 0 to 50 mm) is cleaned with the lower surface brush. At this time, cleaning liquid is supplied from the liquid nozzle to the lower surface of the substrate, and band-shaped nitrogen gas is ejected from the gas ejection unit to the lower surface of the substrate.

Thereafter, with the lower surface brush separated from the lower surface of the substrate, a cleaning region is dried with the band-shaped nitrogen gas from the gas ejection unit while moving the gas ejection unit in the Y direction. Thereafter, the holding rotation part holds the center region of the lower surface of the substrate with the suction holding part. Thereafter, while rotating the substrate, the remaining outer region of the lower surface of the substrate (a region with a radius of 50 to 150 mm) is cleaned with the lower surface brush. Thereafter, the substrate is rotated at high speed by the holding rotation part to dry the substrate.

When the lower surface brush cleans the lower surface of the substrate, deflection or deformation may occur in the substrate, and the distance between the lower surface brush and the lower surface of the substrate may become non-uniform. When the substrate is deflected, the lower surface brush does not contact a part of the substrate, thereby reducing the cleaning efficiency of the substrate. Conventionally, as a configuration to avoid the decrease in cleaning efficiency caused by deflection, a configuration has been proposed in which an elastic body is arranged between a polishing member constituting the lower surface brush and a rotating base (see, for example, Japanese Patent Application Laid-Open Publication No. 2013-179252). By the elastic body deforming in accordance with the deflection of the substrate, the polishing member of the lower surface brush may be made to suitably follow the lower surface of the substrate.

However, in the case of the conventional example having such a configuration, there is the following problem. That is, in the configuration of Japanese Patent Application Laid-Open Publication No. 2013-179252, it is possible to bring the polishing member of the lower surface brush into contact with the entire lower surface of the substrate. However, in the configuration of Japanese Patent Application Laid-Open Publication No. 2013-179252, there is a concern about a new problem that when the lower surface brush cleans the lower surface of the substrate, the pressing force acting from the polishing member on the lower surface of the substrate becomes non-uniform on the lower surface of the substrate.

The following may be considered as causes of the pressing force becoming non-uniform. That is, in the configuration of Japanese Patent Application Laid-Open Publication No. 2013-179252, the entire polishing member is mounted on the elastic body. In a portion of the polishing member where the distance from the lower surface of the substrate is relatively large, the elastic body on which the polishing member is mounted does not elastically deform. In this case, the pressing force acting on the lower surface of the substrate is relatively small. On the other hand, in a portion of the polishing member where the distance from the lower surface of the substrate is relatively small, the elastic body on which the polishing member is mounted elastically deforms. In this case, since the reaction force generated from the elastic body acts on the lower surface of the substrate, the pressing force acting on the lower surface of the substrate becomes relatively large. Therefore, it is considered that when deflection occurs in the substrate and the distance between the lower surface of the substrate and the polishing member becomes non-uniform, the pressing force acting from the polishing member on the lower surface of the substrate becomes non-uniform.

When the pressing force acting from the polishing member on the substrate becomes non-uniform, there is a concern about a problem that the cleaning efficiency of the substrate becomes non-uniform. Moreover, when the pressing force acting on the substrate becomes non-uniform, there is also a concern about a problem that deformation or damage occurs in the substrate at portions where the pressing force is large.

The disclosure has been made in view of such circumstances, and an object thereof is to provide a substrate processing device capable of making the pressing force acting during cleaning of the substrate uniform even when deflection or deformation of the substrate occurs.

### SUMMARY

A substrate processing device includes a plurality of cleaning members arranged in parallel in a radial direction of a substrate and cleaning the substrate; a support member supporting the plurality of cleaning members; a rotary drive part causing the support member to relatively rotate with respect to the substrate; a plurality of connecting members connecting each of the plurality of cleaning members and the support member and each being capable of moving up and down independently; and a pressing force adjustment mechanism causing the plurality of connecting members to move up and down respectively such that each of pressing forces exerted on the substrate by each of the plurality of cleaning members becomes uniform.

### BRIEF DESCRIPTION OF THE DRAWINGS

FIG. 1 is a plan view showing a schematic configuration of a substrate processing device according to Embodiment 1.

FIG. 2 is a side view showing a schematic configuration of a substrate processing device according to Embodiment 1.

FIG. 3 is a plan view of a cleaning brush according to Embodiment 1.

FIG. 4 is a side view describing an overall configuration of a cleaning brush according to Embodiment 1.

FIG. 5 is a longitudinal sectional view describing a main part of a cleaning brush according to Embodiment 1.

FIG. 6 is a functional block diagram of a substrate processing device according to Embodiment 1.

FIG. 7 is a flowchart showing an outline of operation of a substrate processing device according to Embodiment 1.

FIG. 8 is a flowchart describing detailed steps of Step S4 according to Embodiment 1.

FIG. 9 is a plan view describing Step S1 according to Embodiment 1.

FIG. 10 is a side view describing Step S2 according to Embodiment 1.

FIG. 11 is a side view describing Step S3 according to Embodiment 1.

FIG. 12 is a side view describing Step S4 according to Embodiment 1.

FIG. 13 is a side view describing Step S5 according to Embodiment 1.

FIG. 14 is a side view describing Step S6 according to Embodiment 1.

FIG. 15 is a side view describing Step S7 according to Embodiment 1.

FIG. 16 is a side view describing Step S8 according to Embodiment 1.

FIG. 17 is a side view describing Step S9 according to Embodiment 1.

FIG. 18 is a side view describing Step S10 according to Embodiment 1.

FIG. 19 is a side view describing Step S11 according to Embodiment 1.

FIG. 20 is a side view describing Step S13 according to Embodiment 1.

FIG. 21 is a side view describing Step S14 according to Embodiment 1.

FIG. 22 is a side view describing Step S15 according to Embodiment 1.

FIG. 23 is a side view describing Step S17 according to Embodiment 1.

FIG. 24 is a side view describing Step S17 according to Embodiment 1.

FIG. 25 is a side view describing a state in which the substrate is deflected in Step S3 according to Embodiment 1.

FIG. 26 is a side view describing non-uniformity of pressing force of the brush body in Step S3 according to Embodiment 1.

FIG. 27 is a side view describing Step SA and Step SB according to Embodiment 1.

FIG. 28 is a side view describing Step SC according to Embodiment 1.

FIG. 29 is a side view describing Step SD according to Embodiment 1.

FIG. 30 is a side view describing non-uniformity of pressing force of the brush body in Step S7 according to Embodiment 1.

FIG. 31 is a side view describing Step SD according to Embodiment 1.

FIG. 32 is a plan view of the cleaning brush according to Embodiment 2.

FIG. 33 is a plan view showing a positional relationship between the brush body and the substrate according to Embodiment 1.

FIG. 34 is a plan view showing a cleaning region according to Embodiment 1.

FIG. 35 is a plan view showing a cleaning region according to Embodiment 2.

FIG. 36 is a plan view of the cleaning brush according to Embodiment 3.

FIG. 37 is a plan view showing a positional relationship between the brush body and the substrate according to Embodiment 3.

FIGS. 38A to 38D are side views showing a cleaning step of a substrate W according to Embodiment 3.

FIG. 39 is a side view of the cleaning brush according to a modification example.

FIGS. 40A to 40B are diagrams describing problems of the cleaning brush according to a conventional example.

FIGS. 41A to 41C are diagrams describing problems of the cleaning brush according to a conventional example.

### DESCRIPTION OF THE EMBODIMENTS

The disclosure adopts the following configuration.

That is, a substrate processing device according to first aspect includes a plurality of cleaning members arranged in parallel in a radial direction of a substrate and cleaning the substrate; a support member supporting the plurality of cleaning members; a rotary drive part causing the support member to relatively rotate with respect to the substrate; a plurality of connecting members connecting each of the plurality of cleaning members and the support member and each being capable of moving up and down independently; and a pressing force adjustment mechanism causing the plurality of connecting members to move up and down respectively such that each of pressing forces exerted on the substrate by each of the plurality of cleaning members becomes uniform.

[Operation and Effect] According to the substrate processing device of the disclosure, the device includes a plurality of cleaning members cleaning a substrate; a support member supporting the plurality of cleaning members; a plurality of connecting members connecting each of the plurality of cleaning members and the support member; and a pressing force adjustment mechanism. Each of the plurality of connecting members is capable of moving up and down independently. The pressing force adjustment mechanism causes the plurality of connecting members to move up and down respectively such that each of the pressing forces exerted on the substrate by each of the plurality of cleaning members becomes uniform. By having such a configuration, even when deflection or deformation occurs in the substrate, the pressing force adjustment mechanism appropriately moves each of the plurality of connecting members up and down, such that the pressing force acting on the substrate from the plurality of cleaning members becomes uniform. Therefore, it is possible to avoid a decrease in cleaning efficiency of the substrate due to non-uniformity of the pressing force. Moreover, it is also possible to avoid deformation or damage occurring in the substrate due to non-uniformity of the pressing force.

Moreover, in the above-described disclosure, it is preferable that the pressing force adjustment mechanism includes an elevation drive part causing the connecting member to move up and down, a pressure gauge measuring each of the pressing forces, and an elevation drive control part causing each of the connecting members to move up and down to a height at which each of the pressing forces becomes uniform by controlling the elevation drive part according to a value of each of the pressing forces measured by the pressure gauge (second aspect).

[Operation and Effect] According to the substrate processing device of the disclosure, the pressing force adjustment mechanism includes an elevation drive part, a pressure gauge, and an elevation drive control part. The pressure gauge measures each of the pressing forces in each of the plurality of cleaning members. The elevation drive control part controls the elevation drive part according to each value of the pressing force measured by the pressure gauge. By the elevation drive control part controlling the elevation drive part, each of the connecting members moves up and down to a height at which each of the pressing forces becomes uniform. By having such a configuration, the height of each of the connecting members connected to the cleaning members may be independently adjusted with high precision. By adjusting the height of the connecting members with high precision, the height of each of the cleaning members may also be independently adjusted with high precision. Therefore, the pressing force of each of the cleaning members may be uniformized with higher precision.

Moreover, in the above-described disclosure, it is preferable that the pressure gauge is configured to re-measure each of the pressing forces after the elevation drive control part controls the elevation drive part, and the pressing force adjustment mechanism causes the plurality of connecting members to move up and down respectively by feedback control such that each of the pressing forces exerted on the substrate by each of the plurality of cleaning members becomes uniform (third aspect).

[Operation and Effect] According to the substrate processing device of the disclosure, the pressure gauge re-measures each of the pressing forces after the elevation drive control part controls the elevation drive part. Then, the pressing force adjustment mechanism causes the connecting members to move up and down respectively by feedback control based on the re-measured pressing forces such that each of the pressing forces becomes uniform. By performing such feedback control, each of the pressing forces may be repeatedly fine-adjusted. Therefore, the pressing force of each of the cleaning members may be uniformized with higher precision.

Moreover, in the above-described disclosure, it is preferable that the elevation drive part is a plurality of air cylinders arranged to correspond to each of the plurality of connecting members, and the elevation drive control part causes each of the connecting members to move up and down to a height at which each of the pressing forces becomes uniform by controlling an amount of gas supplied to each of the plurality of air cylinders (fourth aspect).

[Operation and Effect] According to the substrate processing device of the disclosure, the elevation drive part is a plurality of air cylinders arranged to correspond to each of the plurality of connecting members. The elevation drive control part controls the amount of gas supplied to each of the plurality of air cylinders to move each of the connecting members up and down to a height at which each of the pressing forces becomes uniform. By arranging an air cylinder for each of the connecting members, the height of each of the connecting members may be adjusted with high precision. Therefore, the pressing force of each of the cleaning members may be uniformized with higher precision.

Moreover, in the above-described disclosure, it is preferable that the pressing force adjustment mechanism causes the plurality of connecting members to move up and down respectively such that each of the pressing forces becomes a predetermined ideal pressing force value (fifth aspect).

[Operation and Effect] According to the substrate processing device of the disclosure, the ideal pressing force value is predetermined. Then, the pressing force adjustment mechanism moves each of the plurality of connecting members up and down such that each of the pressing forces becomes the predetermined ideal pressing force value. Compared to adjustment that uniformizes each of the pressing forces while comparing each of the pressing forces, adjustment that makes each of the pressing forces the ideal pressing force is easier to control. Therefore, the pressing force of each of the cleaning members may be uniformized more easily.

Moreover, in the above-described disclosure, it is preferable that the plurality of cleaning members are arranged in parallel so as to form a plurality of rows extending in the radial direction of the substrate, and the plurality of cleaning members included in a predetermined row are arranged in a zigzag manner with respect to the plurality of cleaning members included in a row adjacent to the predetermined row (sixth aspect).

[Operation and Effect] According to the substrate processing device of the disclosure, the plurality of cleaning members are arranged in parallel so as to form a plurality of rows extending in the radial direction of the substrate. The plurality of cleaning members are arranged in a zigzag pattern for each row. Therefore, portions that the cleaning members in a predetermined row could not completely clean may be reliably cleaned by the cleaning members in other rows. Consequently, the cleaning precision on the substrate can be further improved.

Moreover, in the above-described disclosure, it is preferable that the plurality of cleaning members are composed of materials each having different hardnesses, and the pressing force adjustment mechanism causes the plurality of connecting members to move up and down respectively according to the hardness of each of the plurality of cleaning members such that each of the pressing forces exerted on the substrate by each of the plurality of cleaning members becomes uniform (seventh aspect).

[Operation and Effect] According to the substrate processing device of the disclosure, the plurality of cleaning members are composed of materials having different hardnesses. By changing the hardness of the cleaning member according to the position of the substrate that the cleaning member cleans, suitable cleaning may be performed according to each position of the substrate. Then, the pressing force adjustment mechanism moves the plurality of connecting members up and down according to the hardness of each of the plurality of cleaning members such that each of the pressing forces acting on the substrate becomes uniform. Therefore, even when the hardness of the material differs for each cleaning member, the pressing forces acting on the substrate from the plurality of cleaning members may be uniformized.

Moreover, in the above-described disclosure, it is preferable that the plurality of cleaning members are arranged in parallel so as to form a plurality of brush groups each including two or more of the cleaning members arranged in parallel in the radial direction of the substrate, each of the plurality of brush groups is arranged to align in a circumferential direction of the substrate, the plurality of cleaning members included in the same brush group are all composed of materials having the same cleaning characteristics, the plurality of cleaning members included in different brush groups are composed of materials having mutually different cleaning characteristics, and the pressing force adjustment mechanism causes the plurality of connecting members to move up and down respectively such that each of the pressing forces exerted on the substrate by each of the plurality of cleaning members becomes uniform (eighth aspect).

[Operation and Effect] According to the substrate processing device of the disclosure, the plurality of cleaning members are arranged to form a plurality of brush groups. Each brush group has two or more cleaning members arranged in parallel in the radial direction of the substrate. That is, by the rotary drive part rotating the support member relative to the substrate, the plurality of brush groups in which the cleaning members are arranged in parallel clean the substrate in sequence. That is, since the substrate is cleaned a plurality of times by the plurality of cleaning members, the cleaning efficiency of the substrate can be improved.

Moreover, the plurality of cleaning members included in the same brush group are all composed of materials having the same cleaning characteristics, and the plurality of cleaning members included in different brush groups are composed of materials having mutually different cleaning characteristics. By varying the cleaning characteristics of the materials constituting the cleaning members according to the number of times the substrate is cleaned, more precise cleaning may be performed on the substrate. Then, the pressing force adjustment mechanism moves each of the plurality of connecting members up and down such that each of the pressing forces acting on the substrate becomes uniform. Therefore, even when the cleaning characteristics differ for each cleaning member, the pressing forces acting on the substrate from the plurality of cleaning members may be uniformized.

Moreover, in the above-described disclosure, it is preferable that the plurality of cleaning members are arranged to form a plurality of brush groups each including two or more of the cleaning members arranged in parallel in the radial direction of the substrate, each of the plurality of brush groups is arranged to align in a circumferential direction of the substrate, the plurality of cleaning members included in the same brush group are all composed of materials having the same cleaning characteristics, the plurality of cleaning members included in different brush groups are composed of materials having mutually different cleaning characteristics, and the pressing force adjustment mechanism causes the plurality of connecting members to move up and down respectively such that each of the pressing forces exerted on the substrate by each of the plurality of cleaning members included in the same brush group becomes uniform (ninth aspect).

[Operation and Effect] According to the substrate processing device of the disclosure, the plurality of cleaning members are arranged to form a plurality of brush groups. Each brush group has two or more cleaning members arranged in parallel in the radial direction of the substrate. That is, by the rotary drive part rotating the support member relative to the substrate, the plurality of brush groups in which the cleaning members are arranged in parallel clean the substrate in sequence. That is, since the substrate is cleaned a plurality of times by the plurality of cleaning members, the cleaning efficiency of the substrate can be improved.

Moreover, the plurality of cleaning members included in the same brush group are all composed of materials having the same cleaning characteristics, and the plurality of cleaning members included in different brush groups are composed of materials having mutually different cleaning characteristics. By varying the cleaning characteristics of the materials constituting the cleaning members according to the number of times the substrate is cleaned, more precise cleaning may be performed on the substrate. Then, the pressing force adjustment mechanism moves each of the plurality of connecting members up and down such that each of the pressing forces that each of the cleaning members included in the same brush group exerts on the substrate becomes uniform. Therefore, even when the cleaning characteristics differ for each cleaning member, the pressing forces acting on the substrate from the plurality of cleaning members may be uniformized.

According to the substrate processing device of the disclosure, even when deflection or deformation of the substrate occurs, it is possible to uniformize the pressing force exerted during cleaning of the substrate.

### Embodiment 1

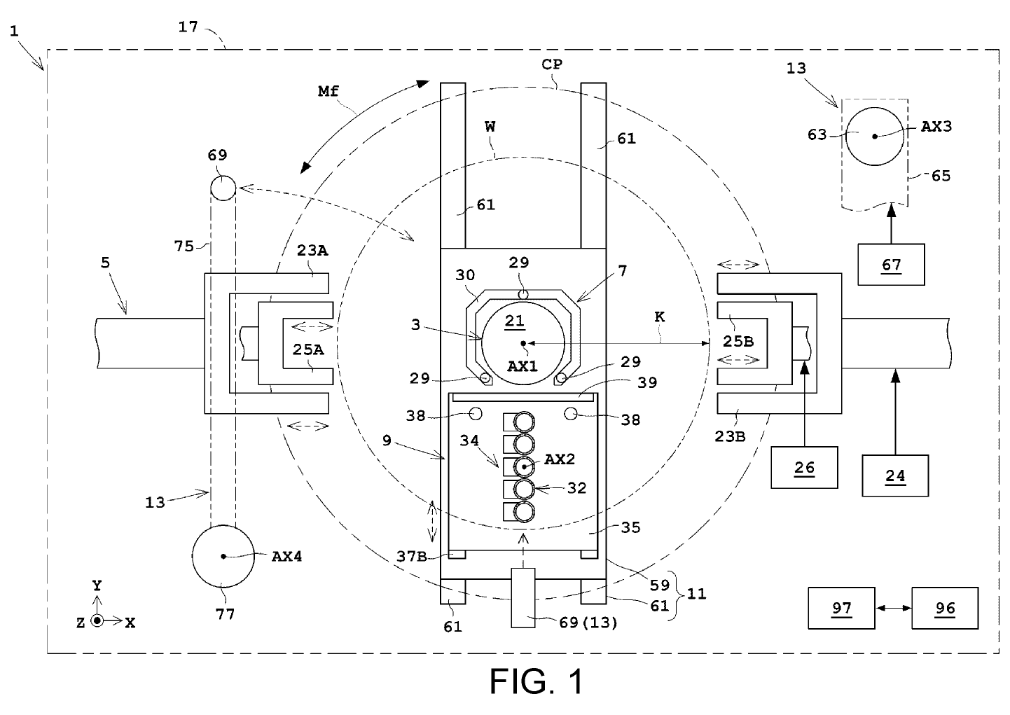

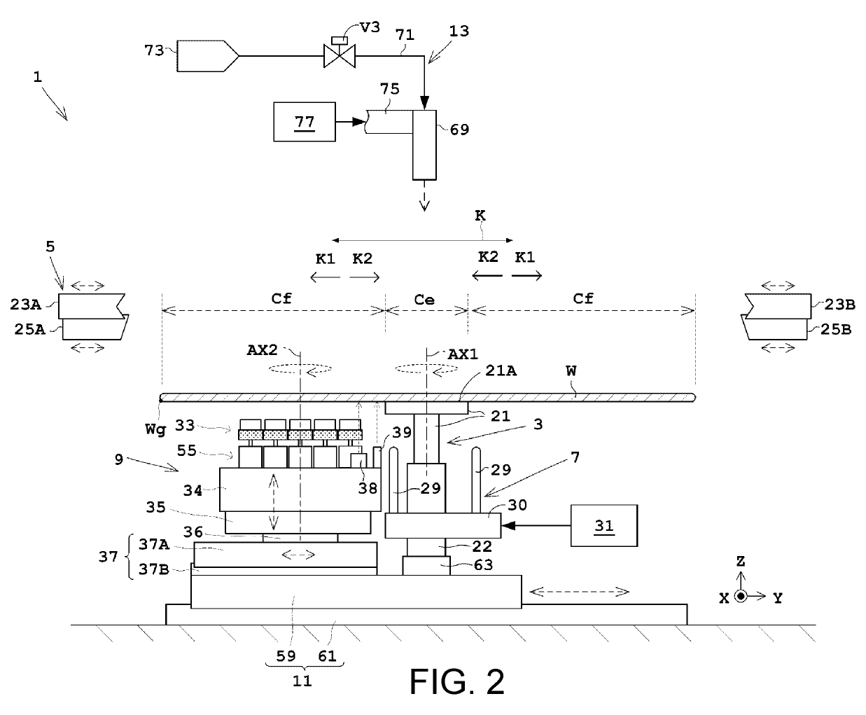

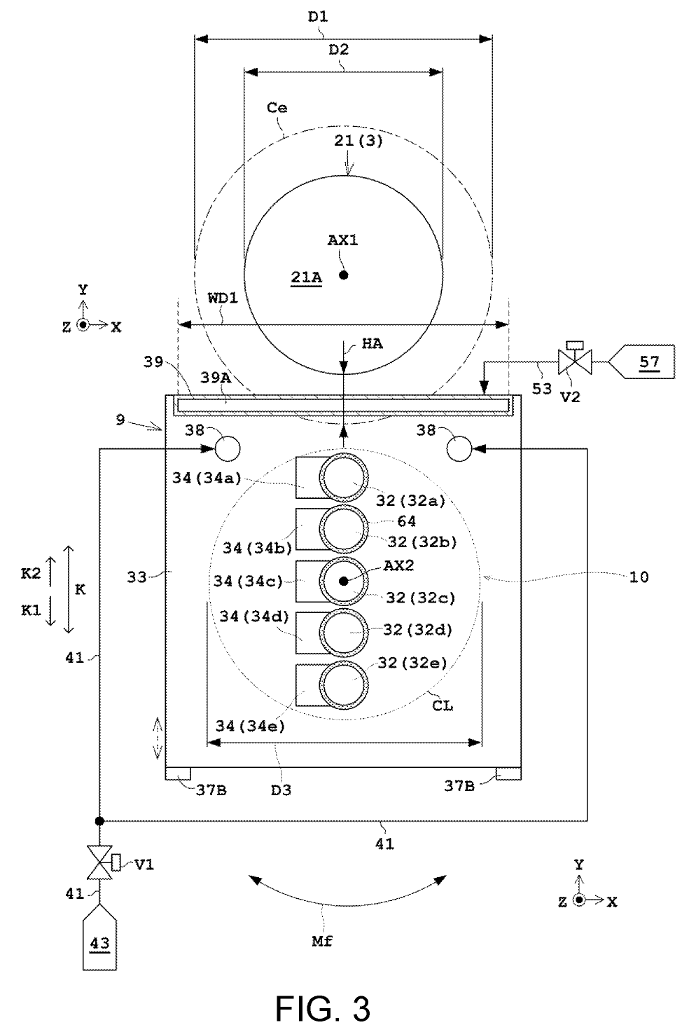

Hereinafter, Embodiment 1 of the disclosure will be described with reference to the drawings. FIG. 1 is a plan view showing a schematic configuration of a substrate processing device 1 according to Embodiment 1. FIG. 2 is a side view showing a schematic configuration of the substrate processing device 1 according to Embodiment 1. In FIG. 2, for convenience of illustration, chucks 23A, 23B and support members 25A, 25B described later are shown as being arranged along the Y direction. FIG. 3 is a plan view showing an ejection nozzle 39 and a configuration near thereof.

### Overall Configuration of Substrate Processing Device

Refer to FIG. 1 and FIG. 2. The substrate processing device (substrate cleaning device) 1 cleans the front surface and the back surface of a substrate W. The substrate processing device 1 includes a holding rotation part 3, a peripheral edge holding part 5, a substrate transport part 7, a back side cleaning mechanism 9, a movable table 11, a front surface cleaning mechanism 13, and a processing chamber 17. Moreover, reference sign CP shown in FIG. 1 indicates an outer shape of a cup (splash prevention cup) that prevents scattering of cleaning liquid and the like. The movable table 11 corresponds to a horizontal movement part of the disclosure.

The processing chamber 17 accommodates the holding rotation part 3, the peripheral edge holding part 5, the substrate transport part 7, the back side cleaning mechanism 9, the movable table 11, and the front surface cleaning mechanism 13. However, two cleaning liquid supply sources 43, 73, an inert gas supply source 57, and three on-off valves V1 to V3 described later may be provided inside the processing chamber 17 or may be provided outside the processing chamber 17.

The holding rotation part 3 holds a back center region of the substrate W. Thereby, the holding rotation part3 holds the substrate W. Moreover, the holding rotation part 3 rotates the substrate W in a horizontal posture around a vertical shaft AX1. Moreover, substrate W is formed, for example, in a disk shape.

The front surface of the substrate W is a surface on a side where an electronic circuit is formed (device surface). In contrast, the back surface of the substrate W is a surface where no electronic circuit is formed. In the embodiment, when processing the substrate W, the orientation of the substrate W is such that the back surface of the substrate W faces downward and the front surface of the substrate W faces upward. Therefore, when the holding rotation part 3 holds the back surface of the substrate W, the holding rotation part 3 holds the lower surface of the substrate W.

The holding rotation part 3 includes a suction holding part 21, a rotary drive part 22, and an elevation drive part 63. The suction holding part 21 has a circular suction surface 21A that vacuum-suctions the back surface (lower surface) of the substrate W. Examples of the suction holding part 21 include a spin chuck or an electrostatic chuck. As shown in FIG. 2, when the suction holding part 21 holds the back surface of the substrate W, a region of the back surface of the substrate W that is suctioned by the suction surface 21A is referred to as a “back center region Ce”. Moreover, a region of the back surface of the substrate W surrounding the back center region Ce is referred to as a “back outer region Cf”. As shown in FIG. 2, in a horizontal direction, a direction from the back center region Ce of the substrate W toward the back outer region Cf is indicated by reference sign K1. In the horizontal direction, a direction from the back outer region Cf of the substrate W toward the back center region Ce is indicated by reference sign K2.

Specifically, the back outer region is a region that may be scrub-cleaned by a plurality of brush bodies 32 described later when the suction holding part 21 holds the back surface of the substrate W. In this case, a region inside the back outer region is the back center region. Moreover, a width HA in FIG. 3 is a width when the plurality of brush bodies 32 are closest to the suction holding part 21 by a Y-direction moving part 37 described later. In this case, the back center region (reference sign Ce) is a circular region with a diameter D1 (diameter D2 + width HA × 2). The diameter D2 is a diameter of an outer diameter of the suction surface 21A of the suction holding part 21.

The rotary drive part 22 rotates the substrate W held by the suction holding part 21 around the vertical shaft AX1 passing through the center of the substrate W. The rotary drive part 22 includes an electric motor as a drive source. The elevation drive part 63 moves the suction holding part 21 up and down together with the rotary drive part 22.

The peripheral edge holding part 5 is arranged above the holding rotation part 3. The peripheral edge holding part 5 holds a peripheral edge of the substrate W. Thereby, the peripheral edge holding part 5 holds the substrate W. The peripheral edge holding part 5 includes two chucks 23A, 23B and a chuck drive part 24. The two chucks 23A, 23B are movable in a horizontal direction (X direction). The two chucks 23A, 23B are arranged facing each other along the X direction so as to sandwich the holding rotation part 3 in a plan view. The two chucks 23A, 23B hold the peripheral edge of the substrate W by sandwiching the substrate W in a horizontal posture.

The chuck drive part 24 moves the chucks 23A, 23B in the X direction. The chuck drive part 24 moves the two chucks 23A, 23B closer to or away from each other. The chuck drive part 24 and a support member drive part 26 described later each include an electric motor.

Moreover, the peripheral edge holding part 5 includes two support members 25A, 25B and a support member drive part 26. The two support members 25A, 25B are movable in a horizontal direction (X direction). The two support members 25A, 25B are arranged facing each other along the X direction so as to sandwich the holding rotation part 3 in a plan view.

When the support members 25A, 25B are moved closer to each other in the X direction, the support member drive part 26 supports a peripheral edge part and the back surface (lower surface) of the substrate W at respective tip parts of the support members 25A, 25B. Moreover, when the support member drive part 26 moves the support members 25A, 25B away from each other, the substrate W in a horizontal posture may be moved in an up-down direction (Z direction) between the support members 25A, 25B. The two chucks 23A, 23B and the two support members 25A, 25B are each formed in a U-shape (C-shape) in a plan view.

Moreover, when the chucks 23A, 23B are moved closer to each other while the substrate W is supported by the support members 25A, 25B, the chucks 23A, 23B may receive the substrate W from the support members 25A, 25B. Moreover, when the chucks 23A, 23B are moved apart, the substrate W may be transferred to the support members 25A, 25B. The peripheral edge holding part 5 is configured such that the substrate W held by the chucks 23A, 23B cannot rotate around a center axis (vertical shaft) of the substrate W.

The substrate transport part 7 transports the substrate W between the holding rotation part 3 and the peripheral edge holding part 5. For example, the substrate transport part 7 transports the substrate W from the holding rotation part 3 to the peripheral edge holding part 5. The substrate transport part 7 is provided near the holding rotation part 3. The substrate transport part 7 includes three support pins 29, a pin connecting member 30, and a pin elevation drive part 31. The number of support pins 29 may be four or more.

The three support pins 29 are arranged so as to surround the suction holding part 21 in a plan view. Moreover, each support pin 29 is arranged in a posture extending in an up-down direction (Z direction). The pin connecting member 30 connects the three support pins 29. The pin elevation drive part 31 causes the three support pins 29 and the pin connecting member 30 to move up and down in the up-down direction. The pin elevation drive part 31 includes an electric motor or an air cylinder.

The back side cleaning mechanism 9 includes a cleaning brush 10, a rotary drive part 35, an elevation drive part 36, a Y-direction moving part 37, two cleaning liquid nozzles 38, and an ejection nozzle 39. The rotary drive part 35, the elevation drive part 36, and the Y-direction moving part 37 each include an electric motor.

As shown in FIGS. 2 to 4, the cleaning brush 10 includes a plurality of brush bodies 32, a brush support member 33, a plurality of linkage mechanisms 34, two cleaning liquid nozzles 38, and an ejection nozzle 39.

The plurality of brush bodies 32 contact the back surface (lower surface) of the substrate W to clean the back surface of the substrate W. Each of the brush bodies 32 is, as an example, a sponge brush formed of a sponge made of PVA (polyvinyl alcohol) as a material. In Embodiment 1, each of the brush bodies 32 is formed in a cylindrical shape or a disk shape. The plurality of brush bodies 32 are arranged in parallel in a radial direction of the substrate W in a plan view. A lower part of each of the brush bodies 32 is accommodated in a holder 64. That is, an upper surface (cleaning surface) of the brush body 32 protrudes upward from the holder 64. A diameter of each of the brush bodies 32 is, as an example, 10 mm to 30 mm. In Embodiment 1, the diameter of each of the brush bodies 32 is assumed to be 20 mm.

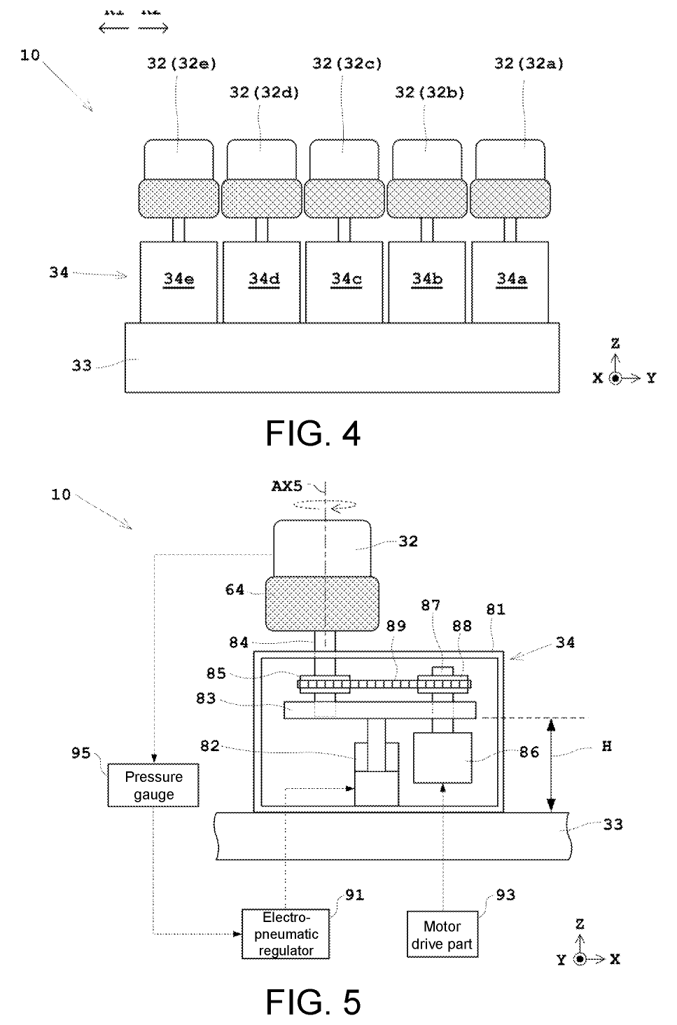

In Embodiment 1, the cleaning brush 10 includes five brush bodies 32. Among the five brush bodies 32, the one arranged at a position closest to the back center region Ce of the substrate W is designated as a brush body 32a to distinguish it from the other brush bodies 32. As shown in FIGS. 3 and 4, among the other four brush bodies 32, those closer to the back center region Ce of the substrate W are designated in order as brush bodies 32b to 32e to distinguish them from the other brush bodies 32. That is, among the five brush bodies 32, the one arranged at a position closest to the back outer region Cf of the substrate W is designated as brush body 32e. In other words, the brush bodies 32a to 32e are arranged so as to align in this order in a direction K1.

The brush support member 33 supports the plurality of brush bodies 32, the plurality of linkage mechanisms 34, the two cleaning liquid nozzles 38, and the ejection nozzle 39. In Embodiment 1, the brush support member 33 is formed in a rectangular columnar shape or a rectangular plate shape. Each of the plurality of linkage mechanisms 34 connects each of the plurality of brush bodies 32 to the brush support member 33. That is, one linkage mechanism 34 connects a corresponding one brush body 32 to the brush support member 33. Therefore, the number of brush bodies 32 included in the cleaning brush 10 is equal to the number of linkage mechanisms 34.

In Embodiment 1, the cleaning brush 10 includes five brush bodies 32. Therefore, the cleaning brush 10 according to Embodiment 1 includes five linkage mechanisms 34. In Embodiment 1, among the five linkage mechanisms 34, the one connecting the brush body 32a and the brush support member 33 is designated as a linkage mechanism 34a to distinguish it from the other linkage mechanisms 34. That is, the linkage mechanism 34a is the linkage mechanism 34 corresponding to the brush body 32a. Similarly, each of the linkage mechanisms 34 corresponding to each of the brush bodies 32b to 32e is designated as linkage mechanisms 34b to 34e to distinguish them from each other. A specific configuration of the linkage mechanism 34 will be described later.

The rotary drive part 35 supports the brush support member 33 rotatably around a vertical shaft AX2. The vertical shaft AX2 passes through a center line of the brush support member 33 which is columnar or plate-shaped. When the brush support member 33 rotates around the vertical shaft AX2, the plurality of brush bodies 32 integrally rotate around the vertical shaft AX2. That is, the rotary drive part 35 integrally rotates the cleaning brush 10 around the vertical shaft AX2.

The elevation drive part 36 supports the rotary drive part 35 such that it may be moved up and down. The elevation drive part 36 causes the plurality of brush bodies 32, the brush support member 33, the plurality of connecting members 34, the rotary drive part 35, the two cleaning liquid nozzles 38, and the ejection nozzle 39 to integrally move up and down in the up-down direction (Z direction). That is, the elevation drive part 36 causes the cleaning brush 10 to integrally move up and down in the up-down direction. Moreover, the elevation drive part 36 moves (moving up and down) the plurality of brush bodies 32 between a cleaning position on the back surface of the substrate W and a separated position that is away from the cleaning position.

The Y-direction moving part 37 supports the elevation drive part 36 movably in the Y direction with respect to the holding rotation part 3. That is, the Y-direction moving part 37 causes the plurality of brush bodies 32, the brush support member 33, the plurality of connecting members 34, the rotary drive part 35, the elevation drive part 36, the cleaning liquid nozzle 38, and the ejection nozzle 39 to integrally move horizontally in the Y direction. The Y-direction moving part 37 includes a slider 37A and a guide rail 37B. The slider 37A supports the elevation drive part 36. The guide rail 37B is arranged to extend in the Y direction and supports the slider 37A movably in the Y direction. An electric motor of the Y-direction moving part 37 moves the slider 37A.

Each of the two cleaning liquid nozzles 38 discharges cleaning liquid. A discharge port of each cleaning liquid nozzle 38 faces upward. Each cleaning liquid nozzle 38 is provided near of the plurality of brush bodies 32 and supplies cleaning liquid to, for example, the back outer region of the substrate W. For example, pure water is used as the cleaning liquid, and for example, deionized water (DIW) is used as the pure water. The number of cleaning liquid nozzles 38 may be one or three or more.

As shown in FIG. 3, a cleaning liquid piping 41 sends cleaning liquid from a cleaning liquid supply source 43 to the two cleaning liquid nozzles 38. The cleaning liquid piping 41 branches into two at a tip side, and the two branched portions are connected to the two cleaning liquid nozzles 38, respectively. A base end of the cleaning liquid piping 41 is connected to the cleaning liquid supply source 43. The cleaning liquid piping 41 is provided with an on-off valve V1. The on-off valve V1 performs supply of the cleaning liquid and stopping of the supply.

The ejection nozzle 39 ejects inert gas to the back center region of the substrate W held by the peripheral edge holding part 5 to dry the back surface of the substrate W. The ejection nozzle 39 ejects inert gas to the back center region of the substrate W held by the peripheral edge holding part 5. As shown in FIG. 3, the ejection nozzle 39 includes a slit-shaped ejection port 39A. The slit-shaped ejection port 39A faces upward, but may face obliquely upward from the ejection nozzle 39 toward the plurality of brush bodies 32. Further, the slit-shaped ejection port 39A is formed to extend longitudinally in the X direction orthogonal to the Y direction. As shown in FIG. 3, a width WD1 of the slit-shaped ejection port 39A is formed to be longer than a diameter D1 of the back center region (reference sign Ce in FIG. 3) in the X direction (width WD1 > diameter D1).

Here, as shown in FIG. 3, a circular region through which the plurality of brush bodies 32 pass when the rotary drive part 35 rotates is defined as a region CL. A diameter of the region CL is defined as D3. In Embodiment 1, a diameter D3 of the region CL is assumed to be equal to or greater than the diameter D1 of the back center region (diameter D3 ≥ diameter D1). In this case, it is preferable that the width WD1 is formed to be longer than the diameter D3 of the region CL (width WD1 > diameter D3).

As shown in FIG. 3, the holding rotation part 3 and the brush support member 33 are arranged along the Y direction in plan view. The ejection nozzle 39 is arranged between the holding rotation part 3 and the brush body 32 in plan view. An inert gas piping 53 is connected to the ejection nozzle 39. A base end of the inert gas piping 53 is connected to an inert gas supply source 57.

The inert gas piping 53 is provided with the on-off valve V2. The inert gas piping 53 sends, for example, nitrogen gas as inert gas from the inert gas supply source 57 to the ejection nozzle 39. The on-off valve V2 performs supply of the nitrogen gas and stopping of the supply.

By setting the on-off valve V2 to an open state, nitrogen gas is sent to the ejection nozzle 39. Therefore, nitrogen gas is ejected from the ejection nozzle 39. The ejection nozzle 39 ejects nitrogen gas when cleaning the back outer region of the substrate W using the back side cleaning mechanism 9. Thereby, a curtain (barrier) of nitrogen gas extending in the X direction may be formed between the plurality of brush bodies 32 and the suction holding part 21.

The movable table 11 moves the holding rotation part 3, the substrate transport part 7, and the back side cleaning mechanism 9 (including the plurality of brush bodies 32 and the ejection nozzle 39) integrally and linearly in a preset Y direction. The movable table 11 includes a slider 59, a guide rail 61, and an electric motor (not shown). The slider 59 supports the holding rotation part 3, the substrate transport part 7, and the back side cleaning mechanism 9. The guide rail 61 supports the slider 59 so as to be movable in the Y direction. The movable table 11 moves the slider 59 on which the holding rotation part 3 and the like are mounted in the Y direction by driving the electric motor.

The front surface cleaning mechanism 13 cleans the front surface (upper surface) of the substrate W whose back center region is held by the holding rotation part 3. The front surface cleaning mechanism 13 includes a cleaning liquid supply nozzle 69, a cleaning liquid piping 71, the cleaning liquid supply source 73, an arm 75, and a nozzle moving part 77.

The cleaning liquid supply nozzle 69 supplies cleaning liquid to the front surface of the substrate W whose back center region Ce is held by the holding rotation part 3. A cleaning liquid piping 71 is connected to the cleaning liquid supply nozzle 69. A base end of the cleaning liquid piping 71 is connected to the cleaning liquid supply source 73. The cleaning liquid piping 71 sends cleaning liquid (for example, DIW) from the cleaning liquid supply source 73 to the cleaning liquid supply nozzle 69. The cleaning liquid piping 71 is provided with the on-off valve V3. The on-off valve V3 performs supply of the cleaning liquid and stopping of the supply.

The arm 75 holds the cleaning liquid supply nozzle 69. The nozzle moving part 77 moves the arm 75 in at least one of the X direction and the Y direction. In Embodiment 1, the nozzle moving part 77 may be configured to rotate the arm 75 around a preset vertical shaft AX4 (see FIG. 1). By the arm 75 moving, the cleaning liquid supply nozzle 69 moves around the vertical shaft AX4 together with the arm 75. The nozzle moving part 77 may be further configured to cause the cleaning liquid supply nozzle 69 to move up and down in the up-down direction (Z direction). The nozzle moving part 77 includes one or more electric motors.

### Configuration of Cleaning Brush

Here, the configuration of the cleaning brush 10 in Embodiment 1, particularly the configuration of the linkage mechanism 34, will be described with reference to FIG. 5 and the like. FIG. 5 is a longitudinal sectional view of the cleaning brush 10. In FIG. 5, for convenience of description, the cleaning liquid nozzle 38 and the ejection nozzle 39 are omitted. FIG. 5 shows a longitudinal section of one brush body 32 and one linkage mechanism 34 connected to the brush body 32. That is, in the cleaning brush 10, the configuration shown in FIG. 5 is arranged in parallel in a plurality of in the radial direction of the substrate W.

Each of the plurality of linkage mechanisms 34 includes a housing 81, an air cylinder 82, a connecting member 83, a rotating shaft 84, a driven pulley 85, a motor 86, a drive shaft 87, a drive pulley 88, and a transmission belt 89. The cleaning brush 10 also includes an electro-pneumatic regulator 91, a motor drive part 93, and a pressure gauge 95. The cleaning brush 10 includes a pressing force adjustment mechanism 15. The pressing force adjustment mechanism 15 includes a plurality of air cylinders 82, an electro-pneumatic regulator 91, and a pressure gauge 95.

The housing 81 is a casing member of the linkage mechanism 34. The housing 81 accommodates the air cylinder 82, the connecting member 83, the rotating shaft 84, the driven pulley 85, the motor 86, the drive shaft 87, the drive pulley 88, and the transmission belt 89. The housing 81 is provided on an upper surface of the brush support member 33.

The air cylinder 82 is arranged on a lower surface of the housing 81. The connecting member 83 is a plate-shaped member extending in a horizontal direction. The rotating shaft 84 is attached to one end side of the connecting member 83, and a drive shaft 87 is attached to the other end side of the connecting member 83. The air cylinder 82 is connected to a central part of the connecting member 83. That is, the air cylinder 82 is connected to a region between the one end side and the other end side of the connecting member 83.

An electro-pneumatic regulator 91 is connected to the air cylinder 82. By supplying air to the air cylinder 82 through the electro-pneumatic regulator 91, the air cylinder 82 moves the connecting member 83 up and down in the up-down direction Z. The movement direction and movement amount of the connecting member 83 in the up-down direction Z change according to the amount of air supplied to the air cylinder 82. As shown in FIG. 5, a distance H between the brush support member 33 and the connecting member 83 is referred to as “height H of the connecting member 83”. The height H of the connecting member 83 changes by the air cylinder 82 and the electro-pneumatic regulator 91.

The rotating shaft 84 extends in the up-down direction Z from one end side of the support member 84. An upper end of the rotating shaft 84 protrudes upward from the housing 81. The upper end of the rotating shaft 84 is connected to the brush body 32. The rotating shaft 84 is provided rotatably around a vertical shaft AX5 passing through a center of the rotating shaft 84. That is, the connecting member 83 connects the brush body 32 and the brush support member 33 through the housing 81, the air cylinder 82, and the rotating shaft 84.

The driven pulley 85 is provided on the rotating shaft 84. The drive shaft 87 extends in the up-down direction Z from the other end side of the connecting member 83. The motor 86 is provided at a lower end of the drive shaft 87. A motor drive part 93 is connected to the motor 86. The drive pulley 88 is provided on the drive shaft 87. The transmission belt 89 is wound around the driven pulley 85 and the drive pulley 88.

The motor drive part 93 rotationally drives the motor 86. By the motor drive part 93 rotationally driving the motor 86, the motor 86 rotates the drive shaft 87. The rotational force of the drive shaft 87 is transmitted to the rotating shaft 84 through the transmission belt 89. That is, by the motor 86 rotationally driving, the rotating shaft 84 rotates around the vertical shaft AX5.

By the rotating shaft 84 rotating around the vertical shaft AX5, the brush body 32 rotates around the up-down direction Z independently of other brush bodies 32. Also, by the air cylinder 82 and the like changing the height H of the connecting member 83, the brush body 32 moves up and down in the up-down direction Z independently of other brush bodies 32. By the brush body 32 moving up and down in a state where the brush body 32 is in contact with the substrate W, a pressing force P acting from the brush body 32 on the substrate W changes.

The pressure gauge 95 measures each of the pressing forces P acting on the substrate W from each of the brush bodies 32. Information of the pressing force P measured by the pressure gauge 95 is transmitted to the electro-pneumatic regulator 91. The pressure gauge 95 is, as an example, a pressure sensor arranged on each of the plurality of brush bodies 32. That is, in Embodiment 1, each of the brush bodies 32a to 32e includes a pressure sensor, and pressing forces Pa to Pe are measured by the pressure sensor.

The electro-pneumatic regulator 91 receives information of the pressing forces Pa to Pe measured by the pressure gauge 95. The electro-pneumatic regulator 91 controls the amount of air supplied from the electro-pneumatic regulator 91 to each of air cylinders 82a to 82e based on the received information of the pressing forces Pa to Pe. By the electro-pneumatic regulator 91 controlling the amount of air, the up and down movement of connecting members 83a to 83e is independently controlled. That is, by the electro-pneumatic regulator 91 controlling the amount of air, heights Ha to He of the connecting members 83a to 83e are independently adjusted.

By controlling the amount of air supplied from the electro-pneumatic regulator 91 to each of the air cylinders 82, the pressing force P acting on the substrate W from each of the brush bodies 32 changes. Each of the changed pressing forces P is measured again by the pressure gauge 95 and transmitted to the electro-pneumatic regulator 91. By such feedback control, the pressing force P acting on the substrate W from each of the brush bodies 32 may be independently controlled.

In this way, each member such as the air cylinder 82, the connecting member 83, and the motor 86 housed in the housing 81 is arranged for each linkage mechanism 34. In Embodiment 1, five linkage mechanisms 34a to 34e are arranged on the cleaning brush 10. Therefore, in Embodiment 1, the number of air cylinders 82, connecting members 83, and motors 86 and the like is five. Hereinafter, the air cylinders 82, connecting members 83, and motors 86 arranged on the linkage mechanisms 34a to 34e are distinguished from each other as air cylinders 82a to 82e, connecting members 83a to 83e, and motors 86a to 86e.

Further, each of the pressing forces P that the brush bodies 32a to 32e apply to the substrate W is distinguished from each other as pressing forces Pa to Pe. And each of the heights H of the connecting members 83a to 83e is distinguished from each other as heights Ha to He. That is, by the pressure gauge 95, the electro-pneumatic regulator 91, and the air cylinders 82a to 82e, the heights Ha to He are independently controlled, and the pressing forces Pa to Pe are independently controlled. That is, the pressing force adjustment mechanism 15 independently adjusts the pressing forces Pa to Pe of the brush bodies 32a to 32e by independently controlling each of the heights Ha to He of the connecting members 83a to 83e.

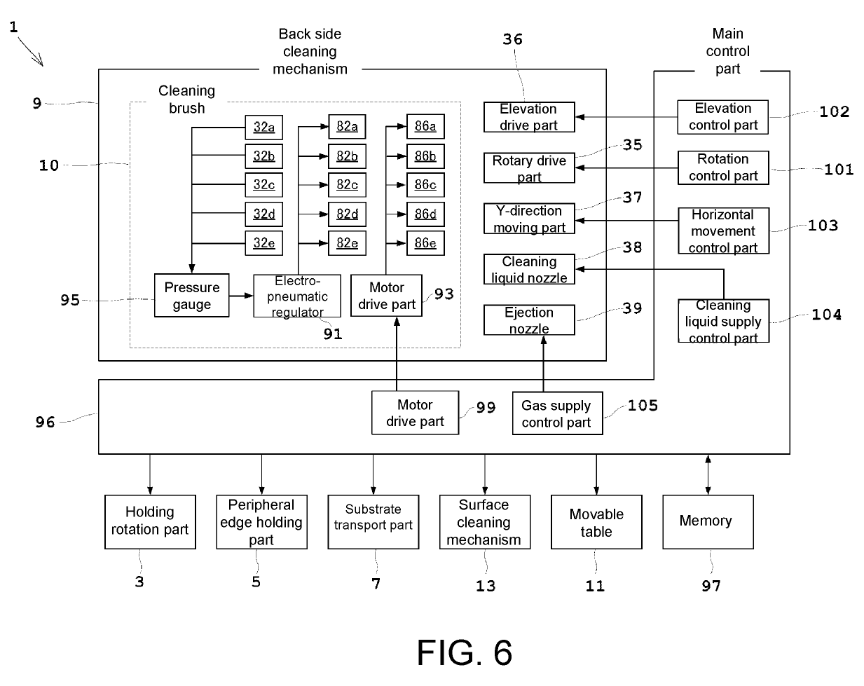

As shown in FIGS. 1 and 6, the substrate processing device 1 includes a main control part 96 and a memory 97. The main control part 96 includes one or more processors, such as a central processing unit (CPU). The main control part 96 comprehensively controls the operation of each configuration in the substrate processing device 1, such as the holding rotation part 3, the peripheral edge holding part 5, the substrate transport part 7, the back side cleaning mechanism 9, the movable table 11, and the front surface cleaning mechanism 13. Further, the main control part 96 controls the cleaning processing of the substrate W.

The memory 97 includes one or more storage media, such as ROM (Read-Only Memory), RAM (Random-Access Memory), and a hard disk. The memory 97 stores computer programs required for controlling each configuration of the substrate processing device 1. The memory 97 may newly store information acquired by the main control part 96. Examples of information newly stored by the memory 97 include information on the pressing force P measured by the pressure gauge 95.

Further, in Embodiment 1, the memory 97 stores the numerical value of an ideal pressing force Pt. The ideal pressing force Pt corresponds to an ideal numerical value as the value of the pressing force P applied from the brush body 32 to the substrate W.

As shown in FIG. 6, the main control part 96 includes a motor control part 99, a rotation control part 101, an elevation control part 102, a horizontal movement control part 103, a cleaning liquid supply control part 104, and a gas supply control part 105.

The motor control part 99 controls the operation of the motor drive part 93. By the motor control part 99 controlling the operation of the motor drive part 93, the rotation of the motors 86a to 86e included in the cleaning brush 10 is controlled. That is, the motor control part 99 controls the operation of the brush bodies 32a to 32e rotating around the vertical shaft AX5.

The rotation control part 101 controls the operation of the rotary drive part 35. The rotary drive part 35 rotatably supports the brush support member 33 of the cleaning brush 10 around the vertical shaft AX2. That is, the rotation control part 101 controls the operation of the cleaning brush 10 rotating integrally around the vertical shaft AX2.

The elevation control part 102 controls the operation of the elevation drive part 36. The elevation drive part 36 causes the rotary drive part 35 of the cleaning brush 10 to move up and down in the up-down direction Z. That is, the elevation control part 102 controls the operation of the cleaning brush 10 moving up and down integrally in the up-down direction Z. In other words, by the control of the elevation control part 102, each of the brush bodies 32a to 32e moves up and down integrally in the up-down direction Z.

The horizontal movement control part 103 controls the operation of the Y-direction moving part 37. The Y-direction moving part 37 moves the elevation drive part 36 in the Y direction relative to the holding rotation part 3. That is, the horizontal movement control part 103 controls the operation of the cleaning brush 10 moving horizontally integrally in the Y direction. The cleaning brush 10 is movable by the Y-direction moving part 37 in the K1 direction or the K2 direction between the lower part of the back center region Ce and the lower part of the back outer region Cf. In other words, the horizontal movement control part 103 controls the operation of the cleaning brush 10 moving horizontally integrally in the K1 direction or the K2 direction.

The cleaning liquid supply control part 104 controls the supply operation of the cleaning liquid through the cleaning liquid nozzle 38. As a specific example, the cleaning liquid supply control part 104 controls the opening and closing operation of the on-off valve V1. By the cleaning liquid supply control part 104 controlling the on-off valve V1, the on/off of the operation of supplying the cleaning liquid from the cleaning liquid supply source 43 to the back surface of the substrate W through the cleaning liquid nozzle 38 may be controlled. Further, by the cleaning liquid supply control part 104 controlling the on-off valve V1, the supply amount of the cleaning liquid to the substrate W may also be controlled.

The gas supply control part 105 controls the supply operation of the inert gas through the ejection nozzle 39. As a specific example, the gas supply control part 105 controls the opening and closing operation of the on-off valve V2. By the gas supply control part 105 controlling the on-off valve V2, the on/off of the operation of supplying the inert gas from the inert gas supply source 57 to the back surface of the substrate W through the ejection nozzle 39 may be controlled. Further, by the gas supply control part 105 controlling the on-off valve V2, the supply amount of the inert gas to the substrate W may also be controlled.

### Overview of Substrate Cleaning processing

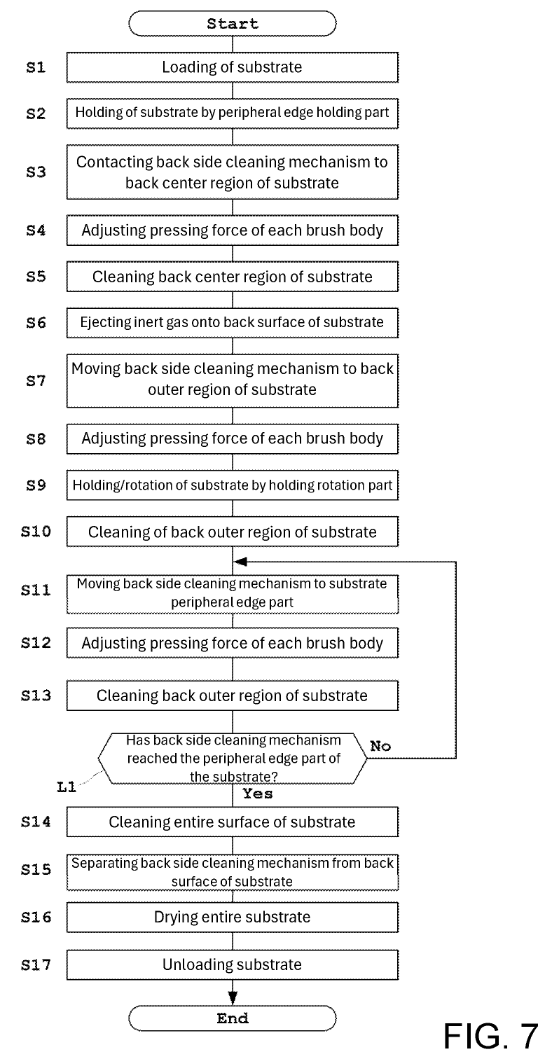

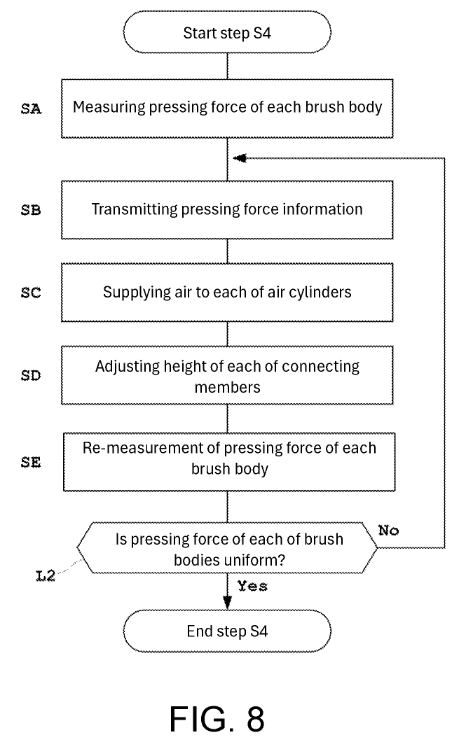

Here, the basic operation of the substrate processing device 1 according to Embodiment 1 is described. FIG. 7 is a flowchart describing an overview of the step of performing cleaning processing on the substrate W using the substrate processing device 1. FIG. 8 is a flowchart describing the details of Step S4 among the cleaning processing steps. In FIG. 10 and the like, for convenience of illustration, the chucks 23A, 23B and the support members 25A, 25B are shown as being arranged along the Y direction. Further, in FIG. 10 and the like, for convenience of illustration, both surfaces of the substrate W are shown as being flat.

Step S1 (loading of substrate)

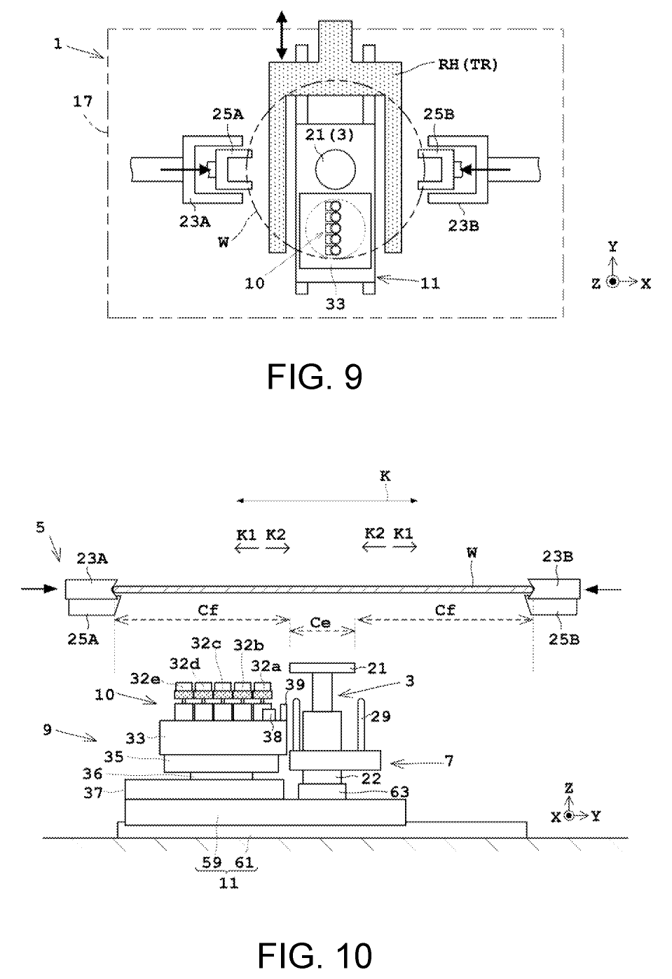

When the cleaning processing step of the substrate W is started, first, the substrate W is loaded into the processing chamber 17. That is, as shown in FIG. 9, the support member drive part 26 (see FIG. 1) of the peripheral edge holding part 5 moves the support members 25A, 25B closer to each other in the X direction. Thereby, the support members 25A, 25B may support the peripheral edge part and the lower surface of the substrate W. Thereafter, a transport robot TR outside the processing chamber 17 loads the substrate W into the inside of the processing chamber 17 by moving a hand RH holding the substrate W into the processing chamber 17.

Step S2 (holding of substrate by peripheral edge holding part)

After loading the substrate W into the inside of the processing chamber 17, the substrate W is held by the peripheral edge holding part 5. That is, the transport robot TR places the substrate W on the support members 25A and 25B of the peripheral edge holding part 5. The front surface of the substrate W placed on the support members 25A, 25B faces upward, and the back surface of the substrate W faces downward. After placing the substrate W on the support members 25A, 25B, the transport robot TR moves the hand RH out of the processing chamber 17. Thereafter, the chuck drive part 24 of the peripheral edge holding part 5 moves the chucks 23A, 23B closer to each other in the X direction. The two chucks 23A, 23B of the peripheral edge holding part 5, as shown in FIG. 10, hold the peripheral edge part of the substrate W by sandwiching the substrate W in a horizontal posture.

Step S3 (contacting back side cleaning mechanism to back center region of substrate)

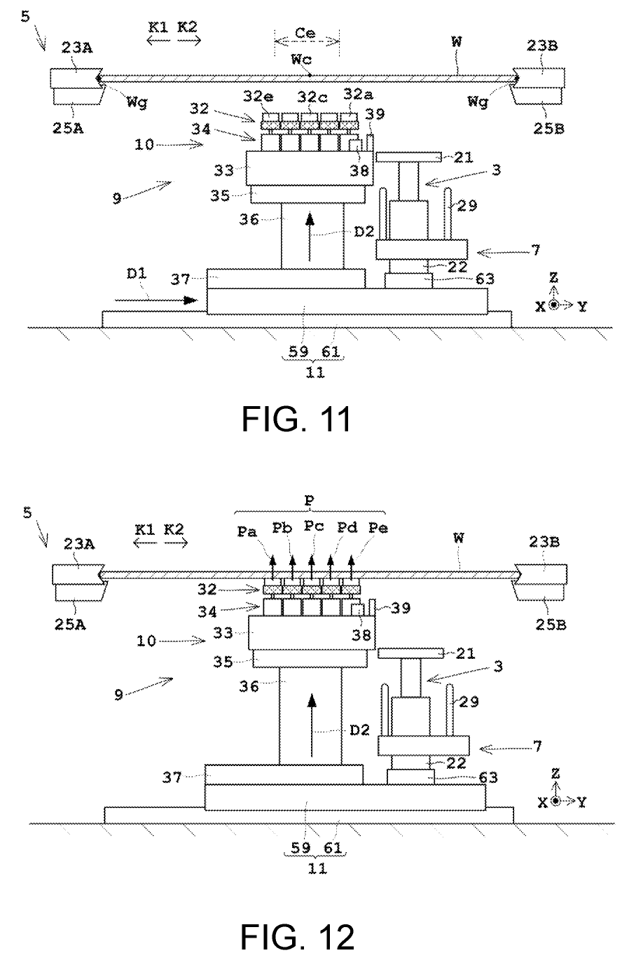

After holding the peripheral edge part of the substrate W by the peripheral edge holding part 5, the cleaning brush 10 of the back side cleaning mechanism 9 is brought into contact with the back center region Ce of the substrate W. That is, as shown in FIG. 11, the movable table 11 moves the back side cleaning mechanism 9 in the direction from the back outer region Cf toward the back center region Ce (K2 direction) (see reference sign D1). That is, the movable table 11 moves the cleaning brush 10 of the back side cleaning mechanism 9 to below the back center region Ce. Further, the elevation drive part 36 causes the cleaning brush 10 to move up as indicated by reference sign D2. By raising the cleaning brush 10, the upper surface of the cleaning brush 10 contacts the back center region Ce of the substrate W. The operation of the elevation drive part 36 in Step S3 is controlled by the elevation control part 102.

Step S4 (adjusting pressing force of each brush body)

After bringing the cleaning brush 10 of the back side cleaning mechanism 9 into contact with the back center region Ce of the substrate W, the pressing force P that each of the brush bodies 32 applies to the substrate W is adjusted. That is, by appropriately moving the connecting member 83 included in each of the linkage mechanisms 34 up and down, each of the brush bodies 32 is brought into contact with the back surface of the substrate W. Furthermore, by appropriately moving each of the connecting members 83 up and down, as shown in FIG. 12, the pressing forces Pa to Pe that each of the five brush bodies 32 applies to the substrate W are adjusted to be uniform. That is, the pressing forces Pa to Pe are adjusted such that the values of the pressing forces Pa to Pe are all equal. Details of the step of uniformly adjusting the pressing forces Pa to Pe in Step S4 will be described later.

Step S5 (cleaning back center region of substrate)

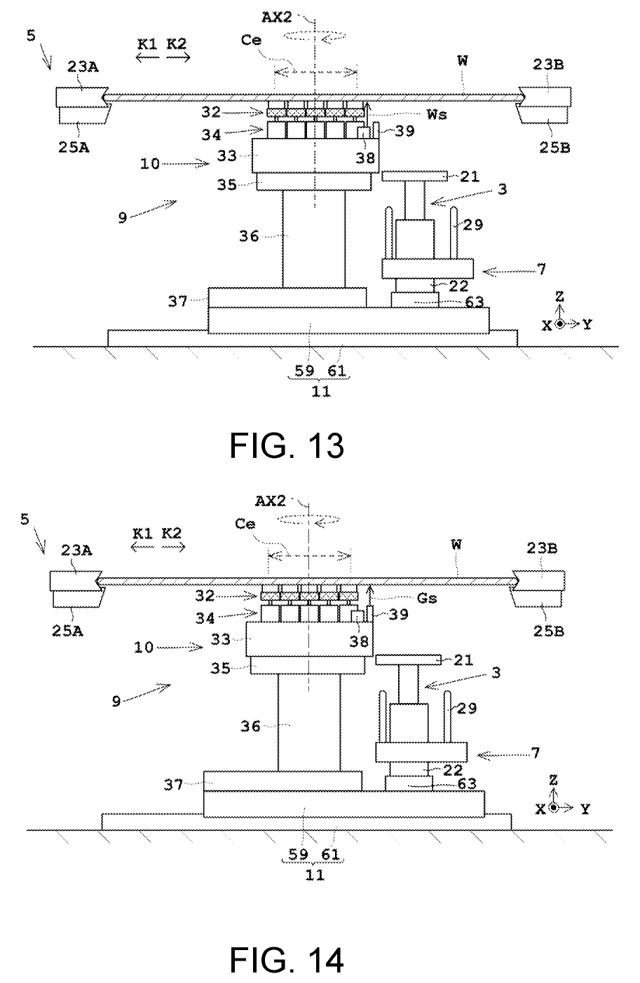

After uniformly adjusting the pressing forces Pa to Pe of each of the brush bodies 32, the back center region Ce of the substrate W is cleaned using the back side cleaning mechanism 9. That is, as shown in FIG. 13, a cleaning liquid Ws is supplied to the back surface of the substrate W from the cleaning liquid nozzle 38. Thereafter, the rotary drive part 35 rotates the entire cleaning brush 10 around the vertical shaft AX2. Further, the motor drive part 93 rotates each of the brush bodies 32 around the vertical shaft AX5 by rotating each of the motors 86 (see FIG. 5). By rotating the entire cleaning brush 10 and each of the brush bodies 32 around the vertical shaft, the back center region Ce of the substrate W is cleaned.

When cleaning the back center region Ce of the substrate W, the pressing forces Pa to Pe of each of the brush bodies 32 are uniformly adjusted. Therefore, the cleaning efficiency of each of the brush bodies 32 with respect to the substrate W becomes uniform. Consequently, it is possible to avoid unevenness in the cleaning efficiency of each of the brush bodies 32 caused by imbalance in the pressing forces Pa to Pe. The operation of the motor drive part 93 in Step S5 is controlled by the motor control part 99. The operation of the rotary drive part 35 in Step S5 is controlled by the rotation control part 101. The operation of supplying the cleaning liquid Ws to the substrate W via the cleaning liquid nozzle 38 is controlled by the cleaning liquid supply control part 104.

Step S6 (ejecting inert gas onto back surface of substrate)

After the back center region Ce of the substrate W is cleaned, inert gas is ejected onto the back surface of the substrate W. That is, as shown in FIG. 14, an inert gas Gs is ejected from the ejection nozzle 39 toward the back surface of the substrate W. Specifically, by ejecting the inert gas Gs from the ejection nozzle 39 toward the back surface of the substrate W, a curtain of the inert gas Gs extending in the X direction is formed between the back side cleaning mechanism 9 and the holding rotation part 3. The operation of ejecting the inert gas Gs to the substrate W via the ejection nozzle 39 is controlled by the gas supply control part 105.

Step S7 (moving back side cleaning mechanism to back outer region of substrate)

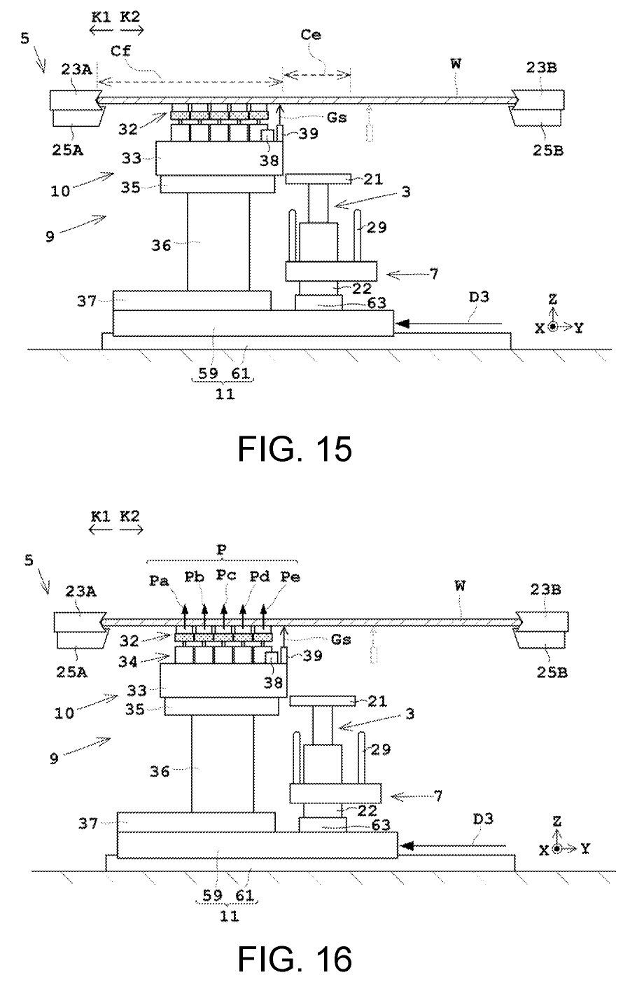

When ejection of the inert gas Gs onto the back surface of the substrate W is started, the back side cleaning mechanism 9 is moved toward the back outer region Cf of the substrate while maintaining the state in which the inert gas Gs is ejected from the ejection nozzle 39. That is, as shown in FIG. 15, the movable table 11 moves the back side cleaning mechanism 9 in the direction from the back center region Ce toward the back outer region Cf (K1 direction) (see reference sign D3). That is, the movable table 11 moves the cleaning brush 10 below the back outer region Cf. When moving the back side cleaning mechanism 9 in the K1 direction, the elevation drive part 36 maintains the cleaning brush 10 in a raised state. In other words, the movable table 11 moves the back side cleaning mechanism 9 in the K1 direction while maintaining the state in which the cleaning brush 10 is in contact with the back surface of the substrate W.

When moving the back side cleaning mechanism 9 in the K1 direction, the operation of rotating the cleaning brush 10 around the vertical shaft AX2 by the rotary drive part 35 may be stopped or continued. Also, when moving the back side cleaning mechanism 9 in the K1 direction, the operation of rotating each of the brush bodies 32 around the vertical shaft AX5 by each of the motors 86 may be stopped or continued.

When cleaning the back center region Ce of the substrate W in Step S5, the cleaning liquid Ws adheres to the back center region Ce of the substrate W. Therefore, the back side cleaning mechanism 9 continues the ejection of the inert gas Gs while moving in the K1 direction from below the back center region Ce to below the back outer region Cf. By moving the back side cleaning mechanism 9 in the K1 direction while continuing the ejection of the inert gas Gs, the ejection nozzle 39 moves relative to the back surface of the substrate W so as to pass through the back center region Ce in plan view while a curtain of the inert gas Gs extending in the X direction is generated. That is, since the curtain of the inert gas Gs extending in the X direction passes through the back center region Ce, the cleaning liquid Ws adhering to the back center region Ce is pushed out to the outside of the back center region Ce by the curtain of the inert gas Gs. As a result, the back center region Ce of the substrate W is dried.

Step S8 (adjusting pressing force of each brush body)

Immediately after starting the operation of moving the back side cleaning mechanism 9 from the back center region Ce to the back outer region Cf, the operation of adjusting the pressing force P that each of the brush bodies 32 applies to the substrate W is started. When the substrate W is precisely flat, even if the back side cleaning mechanism 9 is horizontally moved in the K1 direction, the pressing forces Pa to Pe of each of the brush bodies 32 do not change. That is, even if the back side cleaning mechanism 9 is horizontally moved in the K1 direction, each of the pressing forces Pa to Pe is maintained in a uniform state.

However, when deflection occurs in the substrate W, since the height of the substrate W is not constant, the pressing forces Pa to Pe of each of the brush bodies 32 change by horizontally moving the back side cleaning mechanism 9. That is, by horizontally moving the back side cleaning mechanism 9 in the K1 direction, the pressing forces Pa to Pe become non-uniform again.

Therefore, when the operation of moving the back side cleaning mechanism 9 from below the back center region Ce to below the back outer region Cf is started, the pressing forces Pa to Pe are adjusted again to become uniform. That is, by appropriately moving each of the connecting members 83 up and down, the pressing forces Pa to Pe are adjusted to become uniform as shown in FIG. 16. That is, the pressing forces Pa to Pe are adjusted such that the values of the pressing forces Pa to Pe all become equal again. The step of uniformly adjusting the pressing forces Pa to Pe in Step S8 is the same as the step of adjusting the pressing forces Pa to Pe in Step S4. Therefore, the details of Step S8 will also be described later.

Step S9 (holding of substrate by holding rotation part)

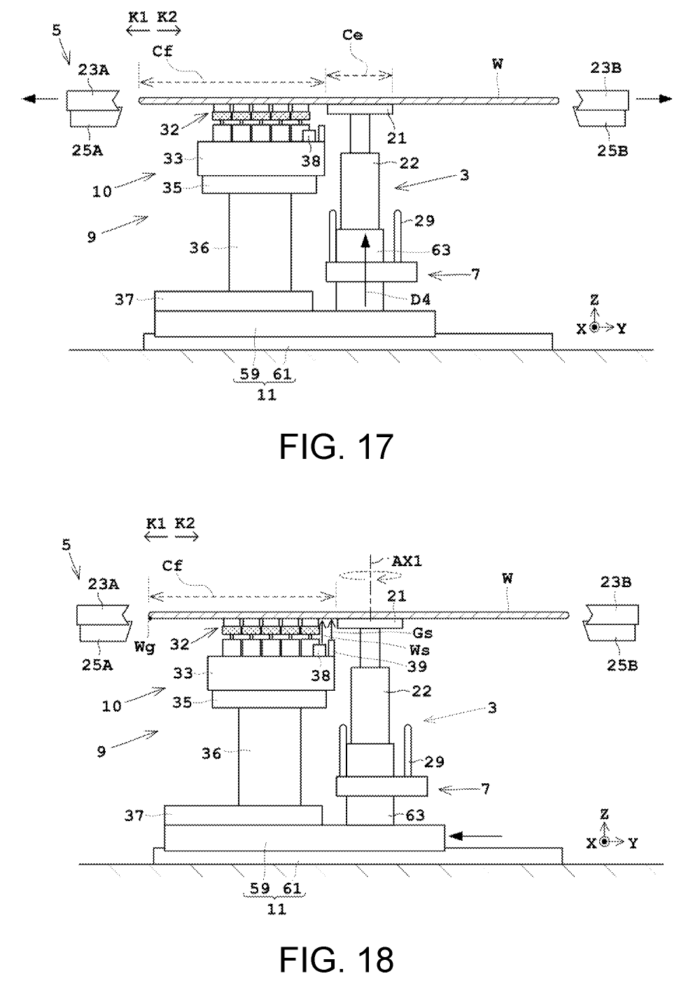

While adjusting the pressing forces Pa to Pe to a uniform state, after the back side cleaning mechanism 9 is moved from below the back center region Ce to below the back outer region Cf, the substrate W is held by the holding rotation part 3. That is, as shown in FIG. 17, the elevation drive part 63 included in the holding rotation part 3 causes the suction holding part 21 to move up together with the rotary drive part 22, as indicated by reference sign D4. As the suction holding part 21 rises and contacts the back surface of the substrate W, the suction surface 21A suction-holds the back center region Ce of the substrate W. By the suction surface 21A suction-holding the back center region Ce, the holding rotation part 3 may hold the back center region Ce of the substrate W.

After holding the back center region Ce of the substrate W by the holding rotation part 3, the chuck drive part 24 moves the chucks 23A and 23B away from each other in the X direction. As shown in FIG. 17, by moving the chucks 23A and 23B away from each other in the X direction, the holding of the substrate W by the peripheral edge holding part 5 is released. By releasing the holding of the substrate W by the peripheral edge holding part 5, rotation of the substrate W by the holding rotation part 3 becomes possible.

Step S10 (cleaning of back outer region of substrate)

After the holding rotation part 3 holds the substrate W and the holding of the substrate W by the peripheral edge holding part 5 is released, the back outer region Cf of the substrate W is cleaned. That is, as shown in FIG. 18, the rotary drive part 22 included in the holding rotation part 3 rotates the substrate W around the vertical shaft AX1. The gas supply control part 105 controls the on-off valve V2 to an open state, thereby ejecting inert gas Gs from the ejection nozzle 39 onto the back surface of the substrate W. By ejecting the inert gas Gs, a curtain of inert gas Gs is formed between the holding rotation part 3 and the back side cleaning mechanism 9. Thereafter, the cleaning liquid supply control part 104 controls the on-off valve V1 to an open state, thereby supplying cleaning liquid Ws from the cleaning liquid nozzle 38 to the back outer region Cf of the substrate W. The curtain of inert gas Gs blocks the cleaning liquid Ws heading toward the holding rotation part 3.

Each of the plurality of brush bodies 32 in contact with the back surface of the substrate W scrub-cleans the back outer region Cf of the substrate W rotating around the vertical shaft AX1 in a state where the cleaning liquid Ws is being supplied. When cleaning the back outer region Cf, the pressing force P that each of the brush bodies 32 applies to the substrate W is uniformly adjusted. Therefore, it is possible to avoid non-uniformity in scrub cleaning efficiency among the plurality of brush bodies 32.

Step S11 (moving back side cleaning mechanism to substrate peripheral edge part)

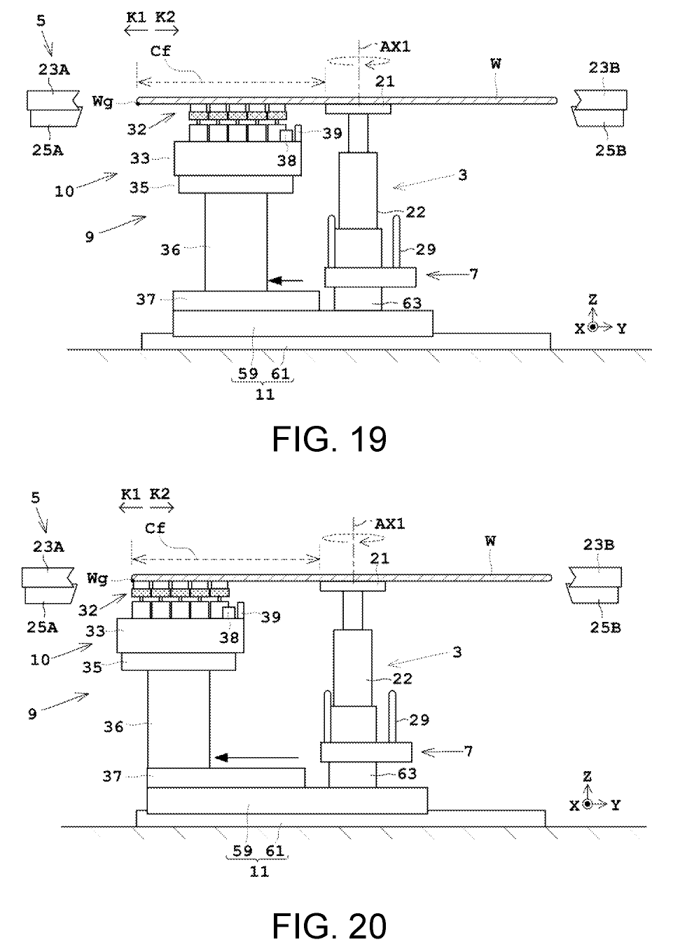

The back side cleaning mechanism 9 performs scrub cleaning of the back outer region Cf by performing the steps of Steps S7 to S10. Thereafter, the back side cleaning mechanism 9 is further moved in the K1 direction toward a substrate peripheral edge part Wg. That is, as shown in FIG. 19, the Y-direction moving part 37 horizontally moves the back side cleaning mechanism 9 in the K1 direction independently of the holding rotation part 3. That is, by the operation of the Y-direction moving part 37, in a state where the holding rotation part 3 is holding the back center region Ce of the substrate W, the cleaning brush 10 of the back side cleaning mechanism 9 moves in the K1 direction toward the peripheral edge part Wg of the substrate W.

Step S12 (adjusting pressing force of each brush body)

Immediately after starting the operation of moving the back side cleaning mechanism 9 to the peripheral edge part Wg of the substrate W, the operation of adjusting the pressing force P that each of the brush bodies 32 applies to the substrate W is started. That is, by appropriately moving each of the connecting members 83 up and down, the pressing forces Pa to Pe are adjusted to be uniform. That is, the pressing forces Pa to Pe are adjusted such that the values of the pressing forces Pa to Pe all become equal again. The step of uniformly adjusting the pressing forces Pa to Pe in Step S12 is the same as the step of adjusting the pressing forces Pa to Pe in Step S4. Therefore, the details of Step S12 will also be described later.

Step S13 (cleaning back outer region of substrate)

The cleaning brush 10 of the back side cleaning mechanism 9 continues scrub cleaning of the back outer region Cf while moving in the K1 direction toward the peripheral edge part Wg of the substrate W. Since the step of Step S13 is the same as the step of Step S10, detailed illustration and description are omitted. That is, while the Y-direction moving part 37 moves the back side cleaning mechanism 9 in the K1 direction, rotation of the holding rotation part 3, supply of the cleaning liquid Ws via the cleaning liquid nozzle 38, and ejection of the inert gas Gs via the ejection nozzle 39 are performed. By cleaning the back outer region Cf of the substrate W while moving the back side cleaning mechanism 9 in the K1 direction, the back outer region Cf of the substrate W is gradually cleaned from the inner peripheral side toward the outer peripheral side.

Here, the step branches depending on whether or not the cleaning brush 10 of the back side cleaning mechanism 9 has reached the peripheral edge part Wg of the back surface of the substrate W (refer to reference sign L1 in FIG. 7). When the cleaning brush 10 has not reached the peripheral edge part Wg of the back surface of the substrate W, the step returns to Step S11 and repeats the Steps S11 to S13. On the other hand, as shown in FIG. 20, when the brush body 32 of the cleaning brush 10 has reached the peripheral edge part Wg of the back surface of the substrate W, the entire back outer region Cf has been cleaned by the back side cleaning mechanism 9. Therefore, when the cleaning brush 10 has reached the peripheral edge part Wg of the back surface of the substrate W, the process proceeds to the step of Step S14.

Step S14 (cleaning entire surface of substrate)

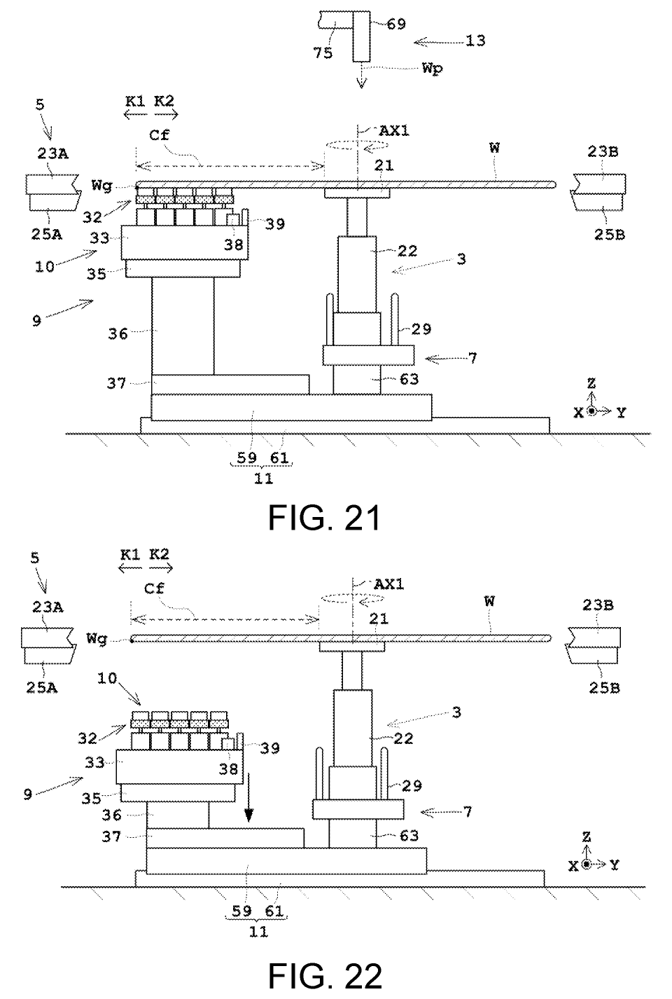

After the entire back outer region Cf of the substrate W has been cleaned, the surface side of the substrate W is cleaned using the surface cleaning mechanism 13. That is, the nozzle moving part 77 of the surface cleaning mechanism 13 rotates the arm 75 around the vertical shaft AX4 (refer to FIG. 1), thereby moving the cleaning liquid supply nozzle 69 above the center of the substrate W, as shown in FIG. 21.

The main control part 96 controls the on-off valve V3 to an open state, thereby supplying a cleaning liquid Wp from the cleaning liquid supply nozzle 69 to the central part of the surface of the substrate W. Since the substrate W is rotating around the vertical shaft AX1, the cleaning liquid Wp supplied to the central part of the surface of the substrate W spreads radially from the central part to the peripheral edge part on the surface of the substrate W. By the cleaning liquid Wp spreading, the entire surface of the substrate W is cleaned by the cleaning liquid Wp. After the surface of the substrate W has been cleaned, the nozzle moving part 77 rotates the arm 75 around the vertical shaft AX4, thereby retracting the cleaning liquid supply nozzle 69 from above the substrate W.

The timing for executing the step of Step S14 is not limited to after the step of Step S13 has been completed. The step of cleaning the surface of the substrate W according to Step S14 may be performed in synchronization with the step of cleaning the back surface of the substrate W. As an example, the step of Step S14 may be performed in parallel with the step of Steps S11 to S13.

Step S15 (separating back side cleaning mechanism from back surface of substrate)

After the cleaning brush 10 of the back side cleaning mechanism 9 reaches the peripheral edge part Wg of the substrate W and the entire back surface of the substrate W has been cleaned, the back side cleaning mechanism 9 is separated from the back surface of the substrate W. When the entire back surface of the substrate W has been cleaned, first, the on-off valve V1 is set to a closed state, thereby stopping the supply of the cleaning liquid Ws from the cleaning liquid nozzle 38. Thereafter, the on-off valve V2 is set to a closed state, thereby stopping the ejection of the inert gas Gs from the ejection nozzle 39. Thereafter, as shown in FIG. 22, the elevation drive part 36 lowers the cleaning brush 10. By lowering the cleaning brush 10, the upper surface of the cleaning brush 10 is separated from the back outer region Cf of the substrate W. The operation of the elevation drive part 36 in Step S15 is controlled by the elevation control part 102.

The timing for performing the step of Step S15 is not limited to after the step of Step S14. That is, after separating the back side cleaning mechanism 9 from the back surface of the substrate W, the surface of the substrate W may be cleaned using the surface cleaning mechanism 13.

Step S16 (drying entire substrate)

After the entire back surface of the substrate W and the entire surface of the substrate W have been cleaned, the entire substrate W is dried. When Step S16 is started, the rotary drive part 22 of the holding rotation part 3 rotates the substrate W at high speed to scatter the droplets adhering to the substrate W. As a result, the substrate W is dried. Thereafter, the rotary drive part 22 stops the rotation of the substrate W, and the suction holding part 21 releases the holding of the substrate W.

Step S17 (unloading substrate)

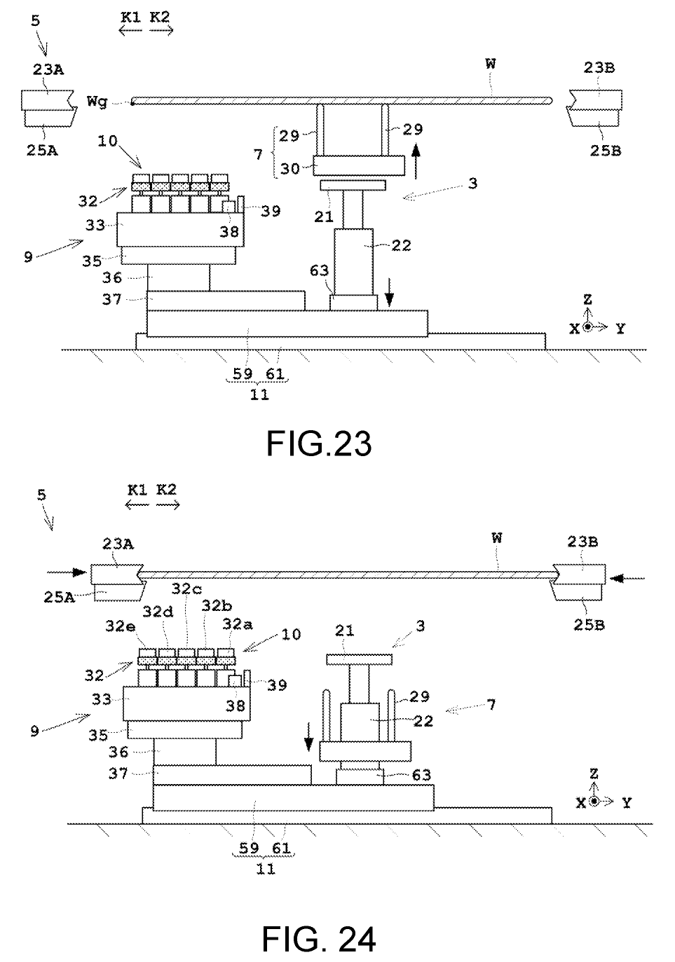

When cleaning and drying of the entire substrate W are completed, the substrate transport part 7 transports the substrate W from the holding rotation part 3 to the peripheral edge holding part 5 and unloads the substrate W. That is, after releasing the holding of the substrate W by the suction holding part 21, as shown in FIG. 23, the pin elevation drive part 31 of the substrate transport part 7 causes the three support pins 29 to move up. As a result, the three support pins 29 receive the substrate W from the suction holding part 21.

Thereafter, as shown in FIG. 24, the support member drive part 26 of the peripheral edge holding part 5 moves the support members 25A, 25B closer to each other in the X direction. Also, the chuck drive part 24 of the peripheral edge holding part 5 moves the chucks 23A, 23B closer to each other in the X direction. The two chucks 23A, 23B of the peripheral edge holding part 5 hold the peripheral edge of the substrate W by sandwiching the substrate W in a horizontal posture.

Thereafter, the pin elevation drive part 31 lowers the three support pins 29 supporting the substrate W. As a result, the substrate W is placed on the support members 25A, 25B. The three support pins 29 are lowered to a standby position where the tip of each support pin 29 is lower than the suction surface 21 of the suction holding part 21A.

Thereafter, the chuck drive part 24 moves the chucks 23A, 23B away from each other in the X direction. As a result, the substrate W is transferred from the chucks 23A, 23B to the support members 25A, 25B. Thereafter, the transport robot TR moves its hand RH into the processing chamber 17 and receives the substrate W placed on the support members 25A, 25B with the hand RH. Thereafter, the transport robot TR moves the hand RH supporting the substrate W out of the processing chamber 17 and transports the substrate W to the next destination. Through the above series of steps, the cleaning step of the substrate W by the substrate processing device 1 is completed.

### Details of Step S4

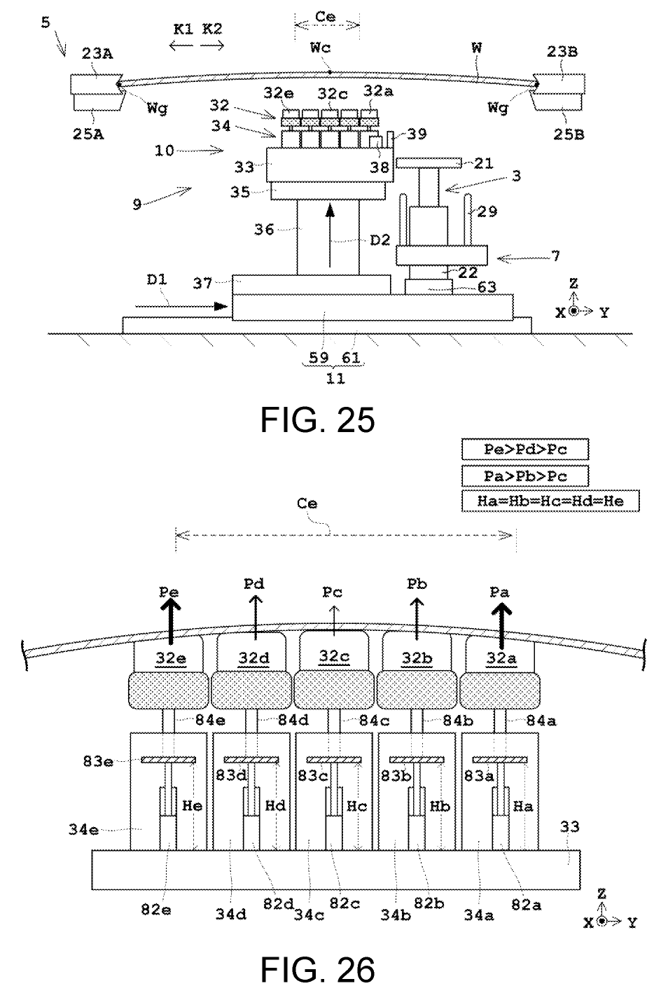

Here, the step of uniformly adjusting each of the pressing forces P in Step S4 is described. In FIG. 11, for convenience of description, the substrate W held in a horizontal posture by the peripheral edge holding part 5 was described as being flat. However, in practice, as shown in FIG. 25, the substrate W held in a horizontal posture by the peripheral edge holding part 5 is assumed to be deflected so as to hang downward from a central part Wc toward the peripheral edge part Wg.

When the substrate W is deflected, the distance from each of the plurality of brush bodies 32 included in the cleaning brush 10 to the substrate W becomes non-uniform. When the distance from the brush body 32 to the substrate W is non-uniform, if the cleaning brush 10 is brought into contact with the substrate W by the elevation drive part 36 in Step S3, the pressing force P acting on the substrate W from each of the brush bodies 32 becomes non-uniform.

FIG. 26 is a diagram showing the pressing force P acting on the substrate W from each of the brush bodies 32 when the cleaning brush 10 contacts the deflected substrate W in Step S3. In FIG. 26 and the like, for convenience of description, the positions of each of the connecting members 83a to 83e in the linkage mechanisms 34a to 34e are shown. Also, in FIG. 26 and the like, the air cylinders 82a to 82e and rotating shafts 84a to 84e are also illustrated.

When the substrate W is deflected so as to hang downward from the central part Wc toward the peripheral edge part Wg, among the five brush bodies 32, the brush body 32c facing the central part Wc of the substrate W is at a relatively far distance from the substrate W. On the other hand, the brush bodies 32a and 32e facing the part of the substrate W that is away from the central part Wc in the K1 direction are at a relatively close distance from the substrate W.

In Step S3, the elevation drive part 36 causes the cleaning brush 10 to integrally move up, such that the cleaning brush 10 contacts the back surface of the substrate W. That is, in Step S3, the air cylinders 82a to 82e are not operated, so the heights Ha to He of the connecting members 83a to 83e are all the same. Therefore, in Step S3, the heights of the upper surfaces of the brush bodies 32a to 32e are all equal.

Therefore, when the substrate W is deflected so as to hang downward, if the elevation drive part 36 causes the cleaning brush 10 to integrally move up, among the five brush bodies 32, the brush bodies 32a and 32e contact the back surface of the substrate W at a relatively early timing and are further pushed upward with a relatively strong force. On the other hand, among the five brush bodies 32, the brush body 32c contacts the back surface of the substrate W at a relatively late timing, so the force pushing it up after contact is relatively weak. As a result, the magnitudes of the pressing forces Pa to Pe that each of the brush bodies 32a to 32e exerts on the substrate W become Pa>Pb>Pc and Pe>Pd>Pc. That is, the magnitudes of the pressing forces Pa to Pe become non-uniform.

Therefore, in the substrate processing device 1 according to Embodiment 1, by executing the step of Step S4, the pressing forces Pa to Pe are uniformly adjusted in a state where each of the brush bodies 32a to 32e is in contact with the substrate W. FIG. 8 is a flowchart showing the details of the step according to Step S4. In Embodiment 1, as an example of a method for uniformizing the pressing forces Pa to Pe, an operation is performed to adjust all of the pressing forces Pa to Pe to the ideal pressing force Pt.

Step SA (measuring the pressing force of each brush body)

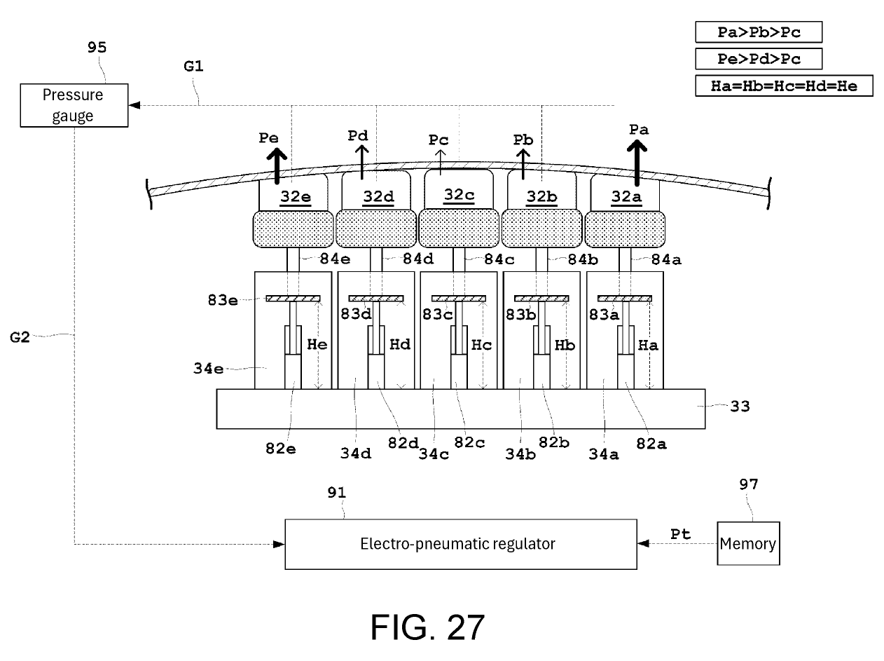

When the step of Step S4 is started, first, the pressing force P that each of the plurality of brush bodies 32 exerts on the substrate W is measured. That is, as shown in FIG. 27, the pressure gauge 95 provided in the cleaning brush 10 measures the pressing forces Pa to Pe by collecting information on the pressing force P from each of the brush bodies 32a to 32e (see reference sign G1). The pressure gauge 95 may detect whether the pressing forces Pa to Pe are uniform or non-uniform by comparing the measured values of the pressing forces Pa to Pe. Moreover, the pressure gauge 95 detects that the magnitudes of the pressing forces Pa to Pe are Pa>Pb>Pc and Pe>Pd>Pc.

Step SB (transmitting pressing force information to the electro-pneumatic regulator)

After measuring the pressing forces Pa to Pe of the brush bodies 32a to 32e, the pressing force P information is transmitted to the electro-pneumatic regulator 91. That is, the pressure gauge 95 transmits the information on the pressing forces Pa to Pe of the brush bodies 32a to 32e obtained by measurement to the electro-pneumatic regulator 91 (see reference sign G2 in FIG. 27).

The electro-pneumatic regulator 91 reads out the information on the ideal pressing force Pt stored in the memory 97. Then, the electro-pneumatic regulator 91 calculates the amount of air to be supplied to each of the air cylinders 82a to 82e by comparing each value of the pressing forces Pa to Pe with the value of the ideal pressing force Pt.

As an example, when the pressing force P of a predetermined brush body 32 is smaller than the ideal pressing force Pt, the electro-pneumatic regulator 91 determines that it is necessary to increase the amount of air supplied to the air cylinder 82 corresponding to that brush body 32. On the other hand, when the pressing force P of a predetermined brush body 32 is larger than the ideal pressing force Pt, the electro-pneumatic regulator 91 determines that it is necessary to decrease the amount of air supplied to the air cylinder 82 corresponding to that brush body 32. The decrease amount and increase amount of air to be supplied are determined according to the magnitude of the difference between the pressing force P of that brush body 32 and the ideal pressing force Pt.

The amounts of air to be supplied to each of the air cylinders 82a to 82e, which the electro-pneumatic regulator 91 calculates in order to make the pressing forces Pa to Pe equal to the ideal pressing force Pt, are referred to as gas supply amounts Ra to Re, respectively. As an example, the gas supply amount Rb is the amount of air that the electro-pneumatic regulator 91 determines should be supplied to the air cylinder 82b in order to make a pressing force Pb that the brush body 32b exerts on the substrate W equal to the ideal pressing force Pt.

The magnitude relationship of the pressing forces Pa to Pe is Pa>Pb>Pc and Pe>Pd>Pc. Therefore, the gas supply amounts Ra to Re calculated by the electro-pneumatic regulator 91 satisfy the relationship Rc > Rb > Ra and Rc > Rd > Re.

Step SC (supplying air to each of the air cylinders)

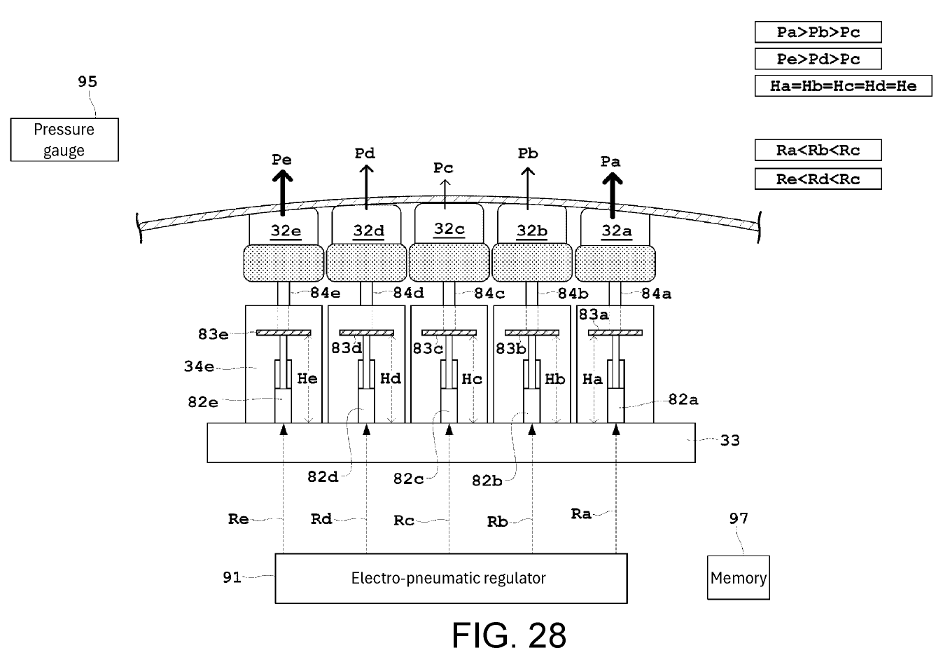

After each of the gas supply amounts Ra to Re is determined by the electro-pneumatic regulator 91, the electro-pneumatic regulator 91 supplies air to each of the plurality of air cylinders 82. That is, as shown in FIG. 28, the electro-pneumatic regulator 91 supplies an amount of air corresponding to the gas supply amount Ra to the air cylinder 82a among the five air cylinders 82. Similarly, the electro-pneumatic regulator 91 supplies amounts of air corresponding to the gas supply amounts Rb to Re to the other air cylinders 82b to 82e, respectively.

Step SD (adjusting the height of each of the connecting members)

When amounts of air corresponding to the gas supply amounts Ra to Re are supplied from the electro-pneumatic regulator 91 to the air cylinders 82a to 82e, respectively, each of the air cylinders 82a to 82e adjusts the height of each of the connecting members 83. As an example, the air cylinder 82a adjusts the height Ha of the connecting member 83a to a height corresponding to the gas supply amount Ra by being supplied with air of the gas supply amount Ra. Similarly, each of the air cylinders 82b to 82e adjusts the heights Hb to He of the connecting members 83b to 83e to heights corresponding to the gas supply amounts Rb to Re.

Each of the connecting members 83 is connected to the upper part of each of the air cylinders 82. Therefore, each of the air cylinders 82 adjusts the height H of the connecting member 83 to a higher position as the amount of supplied gas increases. The gas supply amounts Ra to Re satisfy the relationship Rc > Rb > Ra and Rc > Rd > Re. Accordingly, each of the air cylinders 82a to 82e adjusts the heights Ha to He of the connecting members 83a to 83e such that the relationship Hc > Hb > Ha and Hc > Hd > He is satisfied.

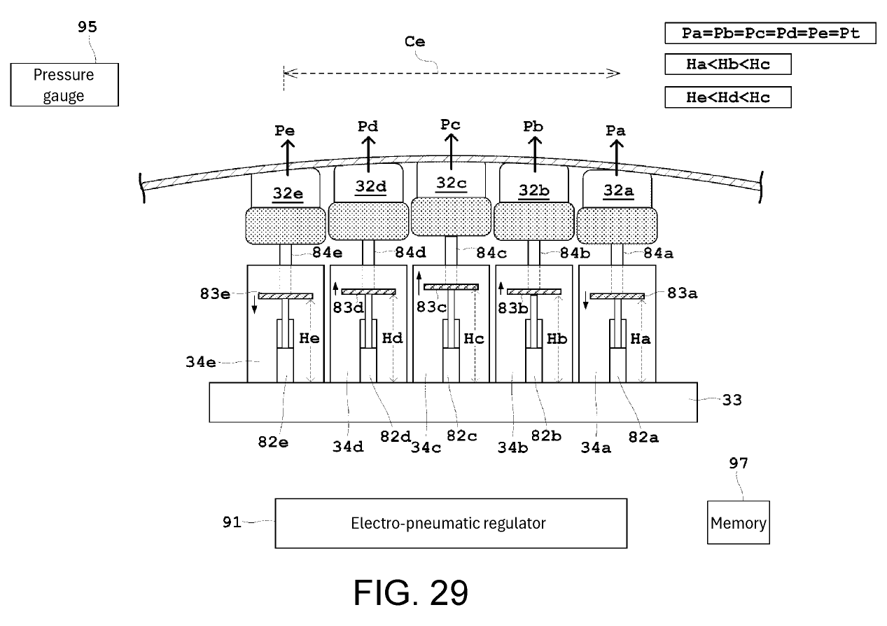

As a specific example, as shown in FIG. 29, the air cylinder 82a performs adjustment to lower the height Ha of the connecting member 83a according to the relatively low gas supply amount Ra. The air cylinder 82c performs adjustment to raise the height Hc of the connecting member 83c according to the relatively high gas supply amount Rc. The air cylinder 82b performs adjustment to slightly raise the height Hb of the connecting member 83b according to the gas supply amount Rb, which is an intermediate value. Similarly, the air cylinder 82d performs adjustment to slightly raise the height Hd of the connecting member 83d according to the gas supply amount Rd, which is an intermediate value. The air cylinder 82e performs adjustment to lower the height He of the connecting member 83e according to the relatively low gas supply amount Re.

Each of the brush bodies 32 is connected to the connecting member 83 via the rotating shaft 84. Therefore, as the height H of the connecting member 83 moves up and down, the height of each of the brush bodies 32 also moves up and down. As an example, when the height of the brush body 32 is lowered, the pressing force P acting from the upper surface of the brush body 32 on the back surface of the substrate W decreases according to the distance by which the brush body 32 is lowered. On the other hand, when the height of the brush body 32 is raised, the pressing force P acting from the upper surface of the brush body 32 on the back surface of the substrate W increases according to the distance by which the brush body 32 is raised. Accordingly, by independently adjusting the height of each of the brush bodies 32, adjustment may be performed to independently increase or decrease each of the pressing forces P of the brush bodies 32.

In this manner, by performing adjustment to increase or decrease the heights Ha to He of the connecting members 83a to 83e respectively according to the values of the pressing forces Pa to Pe before the start of Step S4, as shown in FIG. 29, all of the pressing forces Pa to Pe may be adjusted to the ideal pressing force Pt. That is, by performing the steps of Steps SA to SD, all of the pressing forces Pa to Pe that each of the brush bodies 32a to 32e applies to the substrate W are adjusted to be uniform.

Step SE (re-measurement of pressing force of each brush body)

After the steps of Steps SA to SD are performed, the pressure gauge 95 re-measures each of the pressing forces Pa to Pe of the brush bodies 32. Since the step in which the pressure gauge 95 re-measures the pressing forces Pa to Pe is the same as Step SA, the description is omitted.

After performing Step SE, subsequent steps branch depending on whether the re-measured pressing forces Pa to Pe are uniform or not (refer to reference numeral L2 in FIG. 8). In the case where the re-measured pressing forces Pa to Pe are uniform, since the step of uniformly adjusting each of the pressing forces P is completed, the step of Step S4 ends. On the other hand, in the case where the re-measured pressing forces Pa to Pe are not uniform, the process returns to Step SB and executes the steps of Steps SB to SE. By performing such feedback control, the cleaning brush 10 may repeat adjustment such that each of the pressing forces P becomes uniform for the plurality of brush bodies 32.

The reason for performing the step of uniformly adjusting the pressing force P in Step S8 and Step S12, similar to Step S4, is described. In the case where the brush body 32 of the cleaning brush 10 and the substrate W move relatively, each value of the pressing force P may change. As an example, in the case where the substrate W is rotated while the cleaning brush 10 is in contact with the substrate W, the portion of the substrate W that contacts each of the brush bodies 32 changes. In the case where deflection occurs in the substrate W, the height of the substrate W held in a horizontal posture differs depending on the portion of the substrate W.

Therefore, in the case where deflection occurs in the substrate W, each value of the pressing force P changes by rotating the substrate W. Similarly, in the case where deflection occurs in the substrate W, each value of the pressing force P changes by horizontally moving the cleaning brush 10 while the cleaning brush 10 is in contact with the substrate W. That is, even in the case where adjustment to uniformize each pressing force P of the plurality of brush bodies 32 is completed in advance, uniformity of each pressing force P may be lost by relatively moving the brush bodies 32 and the substrate W. Therefore, in the case where the brush bodies 32 and the substrate W are relatively moved, it is preferable to promptly perform the step of uniformly adjusting the pressing force P.

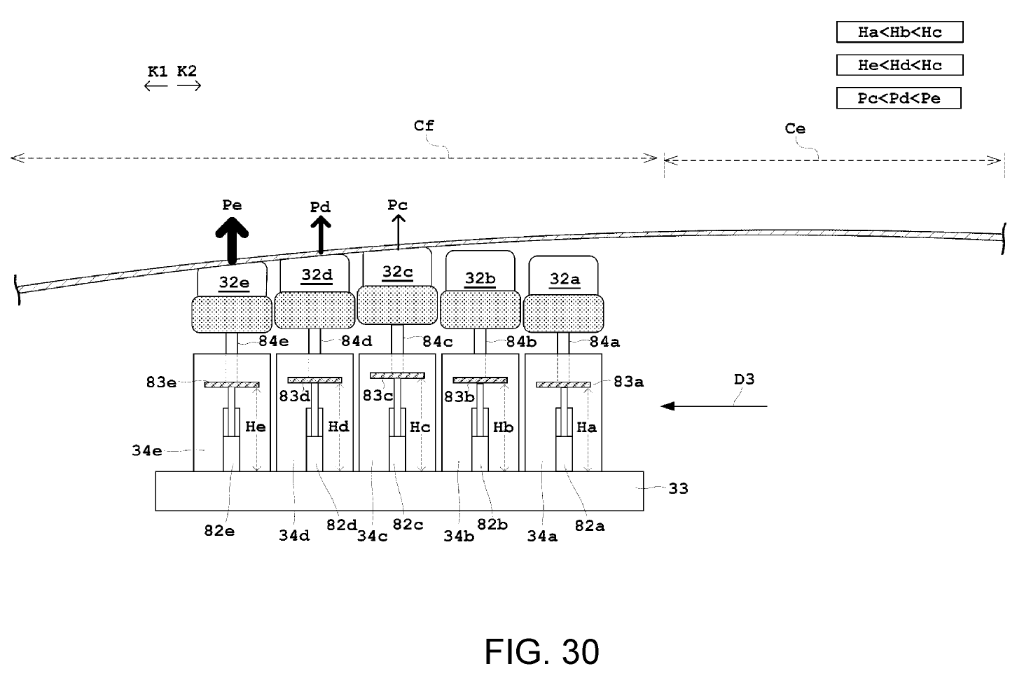

As a specific example, FIG. 30 shows a state in which the step of Step S7 is performed in the case where the substrate W is deflected so as to hang downward. In Step S7, the cleaning brush 10 horizontally moves in the K1 direction from the back center region Ce to the back outer region Cf of the substrate W. In the case where the substrate W is deflected so as to hang downward, the height of the substrate W in the back outer region Cf is lower compared to the height of the substrate W in the back center region Ce. Also, the closer the portion is to the outer periphery of the substrate W, the lower the height of the substrate W becomes. In other words, the height of the substrate W becomes lower toward the K1 direction.

Therefore, as shown in FIG. 30, in the case where the cleaning brush 10 is horizontally moved in the K1 direction in Step S7, the brush body 32e arranged on the outer peripheral side of the substrate W among the five brush bodies 32 faces a portion where the height of the substrate W is lower. Therefore, the brush body 32e contacts the substrate W and further pushes up the substrate W with a strong force. As a result, a pressing force Pe acting on the substrate W from the brush body 32e becomes very large compared to the ideal pressing force Pt.

On the other hand, the brush body 32a arranged on the inner peripheral side of the substrate W among the five brush bodies 32 faces a portion where the height of the substrate W is higher. Therefore, the pressing force Pa acting on the substrate W from the brush body 32a becomes very small compared to the ideal pressing force Pt. Alternatively, since the brush body 32a no longer contacts the substrate W, the pressing force Pa becomes zero. In FIG. 30, as an example, by horizontally moving the cleaning brush 10 in the K1 direction, the relationship Pe>Pd>Pc is established for the pressing forces Pa to Pe, and the pressing forces Pa and Pb become zero. In this way, by the brush bodies 32 moving relatively to the substrate W, there is a possibility that the pressing forces Pa to Pe become non-uniform again.

Therefore, in the case where the back side cleaning mechanism 9 is moved in the K1 direction in Step S7, the step of Step S8 is started to uniformly adjust the pressing forces Pa to Pe. In Step S8, since the steps of Steps SA to SE are performed similarly to Step S4, detailed description is omitted. In the example shown in FIG. 30, the height of the substrate W becomes higher toward the K1 direction. Therefore, the electro-pneumatic regulator 91 adjusts the gas supply amounts Ra to Re supplied to the air cylinders 82a to 82e such that the relationship Ha > Hb > Hc > Hd > He is established for each of the heights Ha to He of the connecting members 83a to 83e.

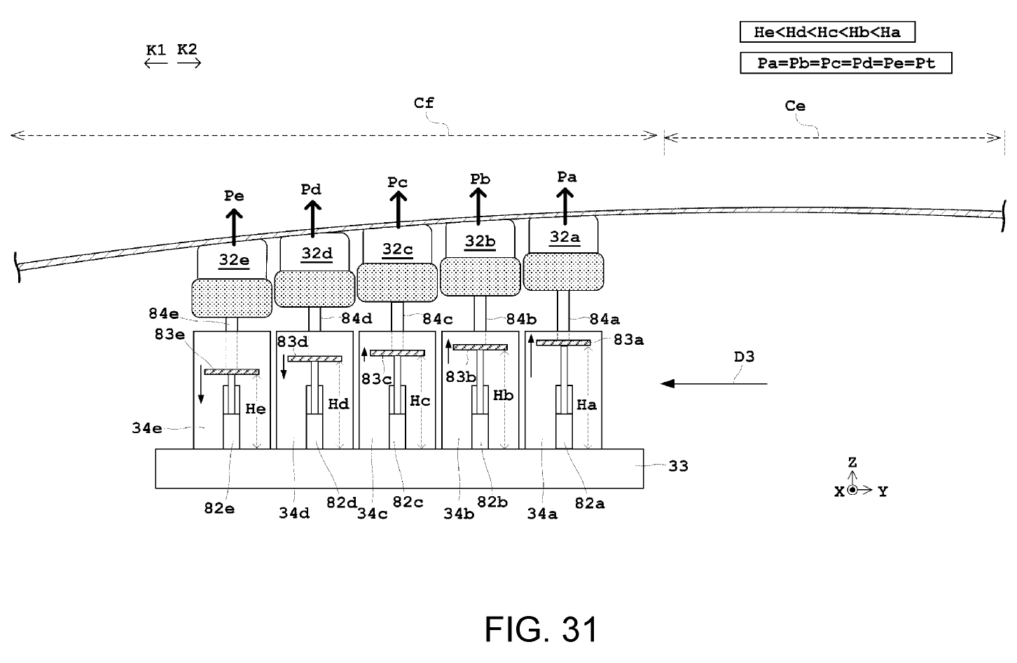

As a result, as shown in FIG. 31, the brush bodies 32a to 32e move up and down to respectively different heights according to each of the heights Ha to He of the connecting members 83a to 83e. Since the heights Ha to He of the connecting members 83a to 83e are values according to the shape of the substrate W where deflection has occurred, each of the pressing forces Pa to Pe acting on the substrate W from the brush bodies 32a to 32e becomes the ideal pressing force Pt again. Therefore, each value of the pressing forces Pa to Pe becomes uniform again.

In this way, even in the case where deflection has occurred on the back surface of the substrate W that is the cleaning target, by performing steps such as Steps S4, S8, and S12 when moving the substrate W relatively to the cleaning brush 10, the pressing forces Pa to Pe may be uniformly adjusted. Therefore, a decrease in cleaning efficiency due to non-uniformity of the pressing forces Pa to Pe can be avoided. Also, occurrence of deformation or damage to the substrate W due to non-uniformity of the pressing forces Pa to Pe can be avoided.

### Effects of the Configuration of Embodiment 1

Here, the effects of the configuration of Embodiment 1 are described by comparing with a conventional configuration. FIG. 40A is a side view showing a cleaning brush 10Y of Japanese Patent Application Laid-Open Publication No. 2024-106198. In the substrate processing device according to Japanese Patent Application Laid-Open Publication No. 2024-106198, the cleaning brush 10Y includes one brush body 32Y having a large diameter. The brush body 32Y is a cylindrical member. The brush body 32Y is supported by a brush support member 33Y. The diameter of the brush body 32Y is approximately 100 mm as an example. Also, the brush support member 33Y moves up and down by a drive part not shown. That is, the brush body 32Y moves up and down in the Z direction by the operation of the brush support member 33Y.

In such a cleaning brush 10Y, the diameter of the brush body 32Y tends to be enlarged in order to improve cleaning efficiency. In such a conventional cleaning brush 10Y, when deflection has occurred in the substrate W, it is difficult to contact the entire substrate W with high precision. FIG. 40B is a side view showing a state where the cleaning brush 10Y is brought into contact with the substrate W where deflection has occurred.

The substrate W shown in FIG. 40B is deflected so as to hang downward from the central part toward the peripheral edge part. When the cleaning brush 10Y is brought close to such a substrate W, a peripheral edge part Tm of the brush body 32Y having a flat upper surface contacts the back surface of the substrate W. On the other hand, a central part Tc of the brush body 32Y is relatively far in distance from the substrate W, making it difficult for it to contact the back surface of the substrate W. Therefore, in the conventional configuration according to Japanese Patent Application Laid-Open Publication No. 2024-106198, it is difficult to make the brush body 32Y of the cleaning brush 10Y suitably follow the shape of the deflected substrate W. As a result, the cleaning efficiency of the substrate by the cleaning brush 10Y decreases.

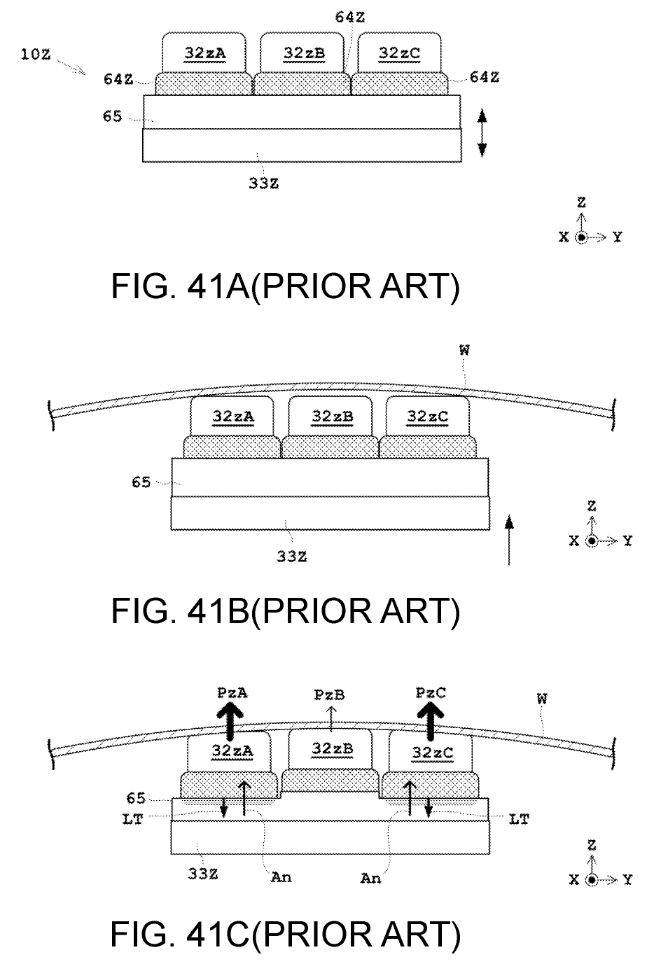

FIG. 41A is a side view showing a conventional cleaning brush 10Z according to Japanese Patent Application Laid-Open Publication No. 2013-179252. In the substrate processing device according to Japanese Patent Application Laid-Open Publication No. 2024-106198, the cleaning brush 10Z includes a plurality of brush bodies 32zA, 32zB, 32zC having small diameters. Each of the brush bodies 32zA, 32zB, 32zC is supported by a brush support member 33Z via one elastic member 65. The brush support member 33Z moves up and down by a drive part not shown. That is, by the operation of the brush support member 33Y, the brush bodies 32zA to 32zC integrally move up and down in the Z direction. The elastic member 65 elastically deforms in the Z direction, thereby causing the brush bodies 32zA to 32zC to follow the substrate W.

FIGS. 41B and 41C are side views showing a state where the cleaning brush 10Y is brought into contact with the substrate W where deflection has occurred. When the cleaning brush 10Z is brought close to the substrate W where deflection has occurred, as shown in FIG. 41B, among the three brush bodies 32zA, 32zB, 32zC, the brush bodies 32zA, 32zC that are relatively close in distance from the substrate W contact the substrate W.

When the brush support member 33Z is further raised in the state shown in FIG. 41B, as shown in FIG. 41C, the brush bodies 32zA, 32zC are further pushed upward while in contact with the substrate W. As a result, as indicated by the reference sign LT, the portions of the elastic member 65 that support the brush bodies 32zA, 32zC elastically deform so as to contract downward. By the partial elastic deformation of the elastic member 65, the brush body 32zB, which is relatively far in distance from the substrate W, also contacts the substrate W. That is, in the cleaning brush 10Z according to Japanese Patent Application Laid-Open Publication No. 2013-179252, by including the elastic member 65, it is possible to cause the upper surface of each of the brush bodies 32zA, 32zB, 32zC to follow the substrate W.

However, in the conventional cleaning brush 10Z according to Japanese Patent Application Laid-Open Publication No. 2013-179252, while the upper surfaces of the brush bodies 32zA to 32zC may follow the substrate W, a new problem occurs. That is, the brush body 32zA and the brush body 32zC, which are close in distance from the substrate W, contact the substrate W at a relatively early timing and are further pushed upward. Therefore, as shown in FIG. 41C, a pressing force PzA with which the brush body 32zA pushes the substrate W upward becomes strong. And a pressing force PzC with which the brush body 32zC pushes the substrate W upward also becomes strong. On the other hand, the brush body 32zB, which is far in distance from the substrate W, contacts the substrate W at a relatively late timing, so the force pushing it upward is weak. Therefore, a pressing force PzB with which the brush body 32zB pushes the substrate W upward becomes weaker compared to the pressing forces PzA, PzC.

Moreover, by the elastic member 65 elastically deforming so as to contract downward, a reaction force An directed upward is generated. That is, in the portions of the elastic member 65 that support the brush bodies 32zA, 32zC, a reaction force An directed upward is generated. As a result, the pressing force PzA and the pressing force PzC that push the substrate W upward are further increased by the addition of the reaction force An. That is, the difference between the pressing force PzA and the pressing force PzB becomes even larger. In this way, in the conventional cleaning brush 10Z according to Japanese Patent Application Laid-Open Publication No. 2013-179252, a new problem occurs in that the pressing forces PzA to PzC acting on the substrate W become non-uniform for the plurality of brush bodies 32zA to 32zC.

In contrast to such a configuration of the conventional example, in the substrate processing device 1 according to Embodiment 1, the cleaning brush 10 includes a plurality of brush bodies 32a to 32e. The plurality of brush bodies 32a to 32e are connected to one brush support member 33 via respectively different connecting members 83a to 83e. Each of the connecting members 83 arranged corresponding to each of the brush bodies 32a to 32e may independently change its height by the air cylinder 82.

That is, in the cleaning brush 10 according to Embodiment 1, in addition to the operation of integrally moving all the brush bodies 32 up and down by the up and down movement of the brush support member 33, by independently adjusting the height of each of the connecting members 83, an operation of independently moving the plurality of brush bodies 32 up and down respectively is possible. Therefore, even when deflection occurs in the substrate W and the height partially differs, each of the plurality of brush bodies 32 may be suitably made to follow the shape of the deflected substrate W. Therefore, poor contact of the brush bodies 32 with the substrate W can be avoided.

The plurality of connecting members 83 are connected to respectively different air cylinders 82. Each of the air cylinders 82 moves only the correspondingly connected connecting member 83 up and down. That is, since one connecting member 83 moves up and down independently from other connecting members 83, one brush body 32 may be moved up and down independently from other brush bodies 32. As an example, the up and down movement of the connecting member 83a does not affect the heights Hb to He of the other connecting members 83b to 83e. Therefore, even if the pressing force Pa of the brush body 32a is changed by the up and down movement of the connecting member 83a, the other pressing forces Pb to Pe do not change. Accordingly, by controlling the operations of the air cylinders 82a to 82e respectively to independently move each of the connecting members 83a to 83e up and down, each of the pressing forces Pa to Pe may be precisely adjusted to a desired value. Therefore, each of the pressing forces Pb to Pe can be easily and reliably adjusted to a uniform value.

### Embodiment 2

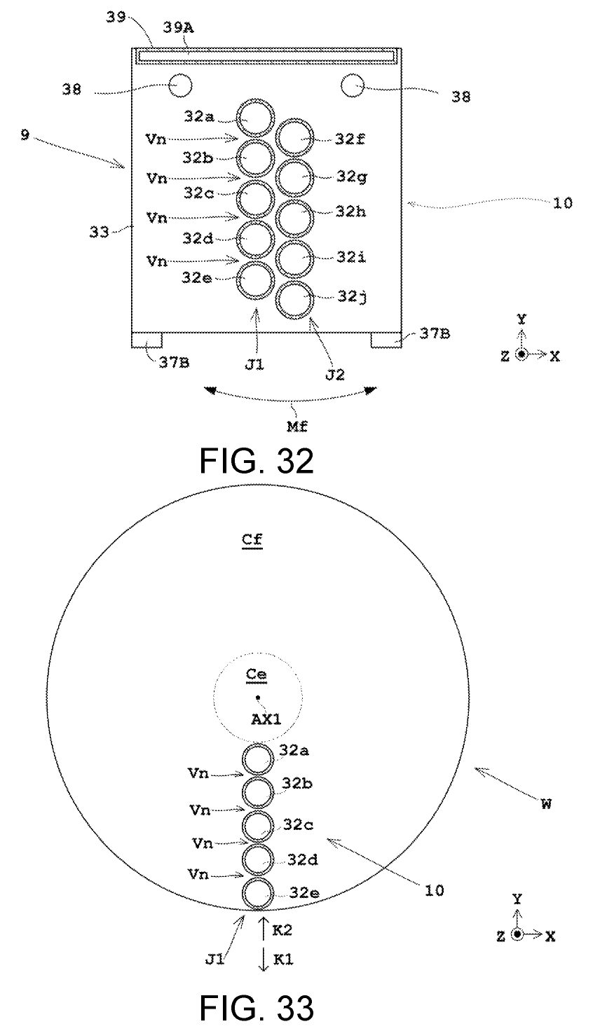

Next, Embodiment 2 of the disclosure will be described with reference to the drawings. Note that configurations overlapping with Embodiment 1 are given the same reference numerals and detailed description thereof is omitted. Embodiment 2 and Embodiment 1 differ in the form in which the plurality of brush bodies 32 are arranged in the cleaning brush 10. Therefore, the configuration characteristic of Embodiment 2 will be described using FIG. 32 and the like. Regarding the configuration of the substrate processing device 1 excluding the cleaning brush 10, the configuration of Embodiment 2 is common with the configuration of Embodiment 1.

FIG. 32 is a plan view of a cleaning brush 10A according to Embodiment 2. In the cleaning brush 10 according to Embodiment 1, as shown in FIG. 3 and the like, the plurality of brush bodies 32a to 32e are arranged so as to align in one row in a radial direction K (K1 direction or K2 direction) of the substrate W. On the other hand, in the cleaning brush 10A according to Embodiment 2, the plurality of brush bodies 32a to 32j are arranged so as to align in a zigzag pattern in the radial direction K of the substrate W. Note that in the plan views from FIG. 32 onward, for convenience of explanation, illustration of the connecting members 34 arranged corresponding to each of the brush bodies 32 is omitted.

The cleaning brush 10A includes a first brush group J1 consisting of a plurality of brush bodies 32 aligned in one row in the radial direction K of the substrate W, and a second brush group J2 consisting of a plurality of brush bodies 32 aligned in one row in the radial direction K of the substrate W. In Embodiment 2, the first brush group J1 includes five brush bodies 32a to 32e. The second brush group J2 includes five brush bodies 32f to 32j. The first brush group J1 and the second brush group J2 are arranged so as to align in a circumferential direction Mf of the substrate W. The number of brush bodies 32 constituting the first brush group J1 and the second brush group J2 may be 2 or more and 4 or less, or may be 6 or more.

In Embodiment 2, the configuration and arrangement of the brush bodies 32a to 32e included in the first brush group J1 are the same as the brush bodies 32a to 32e included in the cleaning brush 10 of Embodiment 1. That is, the cleaning brush 10 according to Embodiment 1 includes only the first brush group J1. On the other hand, the cleaning brush 10A according to Embodiment 2 includes the second brush group J2 in addition to the first brush group J1.

The plurality of brush bodies 32 constituting the first brush group J1 and the plurality of brush bodies 32 constituting the second brush group J2 are arranged so as to be in a zigzag pattern with each other. In the first brush group J1, a gap Vn exists between two brush bodies 32 adjacent in the radial direction K of the substrate W. That is, a gap Vn extending in the circumferential direction Mf of the substrate W exists between the brush body 32a and the brush body 32b. Similarly, the gap Vn also exists between the brush bodies 32b and 32c, between the brush bodies 32c and 32d, and between the brush bodies 32d and 32e.

The second brush group J2 is arranged at positions that supplement each of the gaps Vn existing in the first brush group J1. As an example, the brush body 32f constituting the second brush group J2 is arranged at a position that supplements the gap Vn existing between the brush body 32a and the brush body 32b as viewed from the circumferential direction Mf. Similarly, the brush body 32g is arranged at a position that supplements the gap Vn existing between the brush body 32b and the brush body 32c. The brush body 32h is arranged at a position that supplements the gap Vn existing between the brush body 32c and the brush body 32d. The brush body 32i is arranged at a position that supplements the gap Vn existing between the brush body 32d and the brush body 32e. Therefore, the brush bodies 32a to 32j are arranged in a zigzag pattern as a whole in plan view.

A linkage mechanism 34 is also connected to each of the brush bodies 32 included in the second brush group J2. That is, an air cylinder 82 and a connecting member 83 are each connected to each of the brush bodies 32 included in the second brush group J2. Each of the air cylinders 82 independently moves the connecting member 83 up and down. Therefore, for each of the brush bodies 32f to 32j included in the second brush group J2 as well, connecting members 83f to 83j are independently moved up and down, such that the pressing forces Pf to Pj against the substrate W are adjusted to desired values.

The step of cleaning the substrate W using the substrate processing device 1 including the cleaning brush 10A according to Embodiment 2 is common to the flowchart of Embodiment 1 shown in FIGS. 7 and 8. Therefore, the description of the step according to Embodiment 2 is omitted. In Embodiment 2, similarly to Embodiment 1, each of the pressing forces Pa to Pj acting on the substrate W from each of the brush bodies 32a to 32j may be uniformly adjusted in Step S4 and the like. Therefore, in the cleaning brush 10A according to Embodiment 2, similarly to the cleaning brush 10 according to Embodiment 1, a decrease in cleaning efficiency due to non-uniformity of the pressing forces Pa to Pj can be avoided. Moreover, deformation or damage to the substrate W due to non-uniformity of the pressing forces Pa to Pj can also be avoided.

Here, the effect of the configuration of Embodiment 2 including the cleaning brush 10A is described using FIG. 33 and the like. FIG. 33 is a plan view showing the positional relationship between the brush body 32 and the substrate W in the case of cleaning the back outer region Cf of the substrate W with the cleaning brush 10 according to Embodiment 1. In other words, FIG. 33 corresponds to a plan view showing the positional relationship between the brush body 32 and the substrate W in Step S10 or Step S13 (refer to FIGS. 18 to 20).

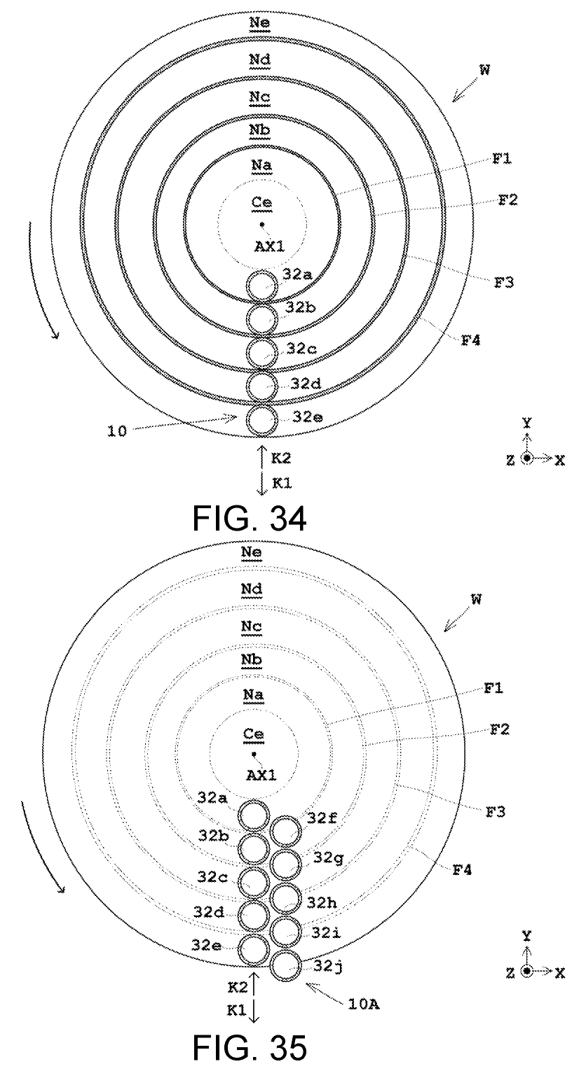

In FIG. 33, the five brush bodies 32a to 32e included in the cleaning brush 10 are aligned in the radial direction of the substrate W in the back outer region Cf. Therefore, when the substrate W is rotated around the vertical shaft AX1 in the state shown in FIG. 33, each of the brush bodies 32a to 32e moves while contacting the back outer region Cf of the substrate W along a circumferential trajectory centered on the vertical shaft AX1. Therefore, the region cleaned by each of the brush bodies 32a to 32e is as shown in FIG. 34.

In FIG. 34, the region cleaned by the brush body 32a is defined as a cleaning region Na. Similarly, the regions cleaned by the brush bodies 32b to 32e are defined as cleaning regions Nb to Ne. Each of the cleaning regions Na to Ne is a ring-shaped region centered on the vertical shaft AX1. However, when the substrate W is rotated around the vertical shaft AX1, the portions of the brush bodies 32 may clean the substrate, while the portions of the gaps Vn formed between two adjacent brush bodies 32 cannot clean the substrate W.

When the substrate W is rotated around the vertical shaft AX1, the gap Vn also moves along a circumferential trajectory similarly to the brush body 32. Therefore, ring-shaped uncleaned regions exist between the cleaning regions Na to Ne. That is, a ring-shaped uncleaned region F1 exists between the cleaning region Na and the cleaning region Nb. The uncleaned region F1 corresponds to a region through which the gap Vn existing between the brush body 32a and the brush body 32b passes. Similarly, a ring-shaped uncleaned region F2 exists between the cleaning region Nb and the cleaning region Nc. A ring-shaped uncleaned region F3 exists between the cleaning region Nc and the cleaning region Nd. A ring-shaped uncleaned region F4 exists between the cleaning region Nd and the cleaning region Ne. In this way, when using the cleaning brush 10 in which there is one row (brush group) of brush bodies 32 aligned in the radial direction of the substrate W, it is difficult to avoid the occurrence of the uncleaned regions F1 to F4.

On the other hand, in the cleaning brush 10A according to Embodiment 2, it is easy to avoid the occurrence of the uncleaned regions F1 to F4. That is, the cleaning brush 10A includes a plurality of rows (brush groups) of brush bodies 32 aligned in the radial direction of the substrate W. In other words, the cleaning brush 10A includes the second brush group J2 in addition to the first brush group J1.

The first brush group J1 and the second brush group J2 are arranged so as to supplement each other's gaps Vn. That is, the plurality of brush bodies 32a to 32j included in the cleaning brush 10A are arranged in a zigzag pattern as a whole. In other words, the plurality of brush groups J1, J2 are arranged so as to complement each other's gaps Vn of the brush bodies 32 (in a zigzag pattern). As an example, the brush body 32f included in the second brush group J2 is arranged to face the gap Vn between the brush body 32a and the brush body 32b in the circumferential direction of the substrate W. Therefore, when the substrate W is cleaned using the cleaning brush 10A, as shown in FIG. 35, the brush body 32f reliably cleans the uncleaned region F1.

Similarly, the brush body 32g is arranged to face the gap Vn between the brush body 32b and the brush body 32c in the circumferential direction of the substrate W. Therefore, the brush body 32g reliably cleans the uncleaned region F2. Furthermore, when the substrate W is cleaned using the cleaning brush 10A, the uncleaned region F3 is reliably cleaned by the brush body 32h. The uncleaned region F4 is reliably cleaned by the brush body 32i. As a result, by using the cleaning brush 10A in which the plurality of brush bodies 32 are arranged in a zigzag pattern, the cleaning efficiency for the substrate W can be greatly improved.

### Embodiment 3

Next, Embodiment 3 of the disclosure will be described with reference to the drawings. Embodiment 3 and Embodiment 1 differ in the form in which the plurality of brush bodies 32 are arranged in the cleaning brush 10. Regarding the configuration of the substrate processing device 1 excluding the cleaning brush 10, the configuration of Embodiment 3 is common to the configuration of Embodiment 1.

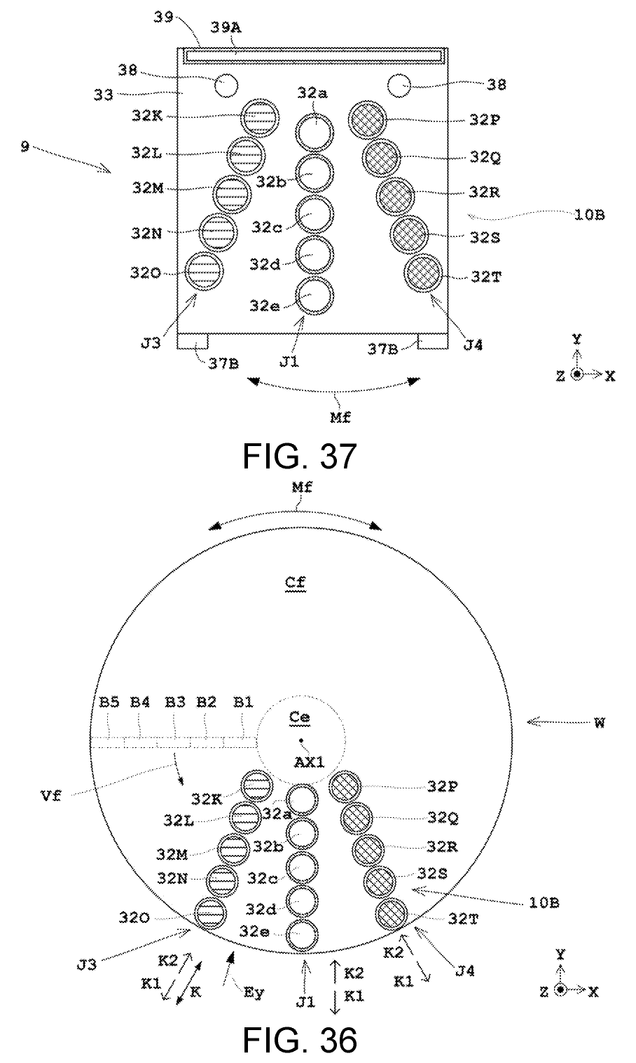

FIG. 36 is a plan view of a cleaning brush 10B according to Embodiment 3. In the cleaning brush 10B according to Embodiment 3, the first brush group J1, the third brush group J3, and a fourth brush group J4 are arranged so as to align in the circumferential direction Mf of the substrate W. Each of the first brush group J1, the third brush group J3, and the fourth brush group J4 includes a plurality of brush bodies 32 aligned in a row in the radial direction of the substrate W.

In Embodiment 3, the first brush group J1 includes five brush bodies 32a to 32e. The third brush group J3 includes five brush bodies 32K to 32O. The fourth brush group J4 includes five brush bodies 32P to 32T. The brush bodies 32K to 32O are arranged so as to align in the direction K1 in this order. The brush bodies 32P to 32T are arranged so as to align in the direction K1 in this order. The number of brush bodies 32 included in the third brush group J3 and the fourth brush group J4 may be 2 or more and 4 or less, or may be 6 or more.

In Embodiment 3, the brush bodies 32 in the first brush group J1, the third brush group J3, and the fourth brush group J4 are each composed of different materials. As the material constituting the brush bodies 32 of the third brush group J3, a material having higher hardness than the material constituting the brush bodies 32 of the first brush group J1 is selected. As the material constituting the brush bodies 32 of the fourth brush group J4, a material having lower hardness than the material constituting the brush bodies 32 of the first brush group J1 is selected.

As a specific example, in Embodiment 3, each of the brush bodies 32a to 32e included in the first brush group J1 is formed of a sponge made of PVA as a material, similar to Embodiment 1. Each of the brush bodies 32K to 32O included in the third brush group J3 is formed of abrasive grains made of an abrasive material such as silicon carbide or diamond. Each of the brush bodies 32P to 32T included in the fourth brush group J4 is formed of a sponge made of a material such as urethane, as an example.

In this manner, in the cleaning brush 10B according to Embodiment 3, the brush bodies 32 belonging to the same brush group are composed of materials having the same cleaning characteristics. And the brush bodies 32 belonging to different brush groups are composed of materials having different cleaning characteristics. As an example of cleaning characteristics, hardness of the material and the like may be mentioned.

The step of cleaning the substrate W using the substrate processing device 1 including the cleaning brush 10B according to Embodiment 3 is common with the flowchart of Embodiment 1 shown in FIGS. 7 and 8. Therefore, description of the step according to Embodiment 2 is omitted. In Embodiment 2, similar to Embodiment 1, in Step S4 and the like, each of the pressing forces Pa to Pe and PK to PT acting on the substrate W from each of the brush bodies 32a to 32e and 32K to 32T may be uniformly adjusted. Therefore, in the cleaning brush 10B according to Embodiment 3, similar to the cleaning brush 10 according to Embodiment 1, a decrease in cleaning efficiency due to non-uniformity of the pressing force P can be avoided. Also, deformation or damage occurring to the substrate W due to the pressing force P becoming non-uniform can be avoided.

In Embodiment 3, the configuration for uniformly adjusting the pressing force P of the plurality of brush bodies 32 is not limited to a configuration in which the electro-pneumatic regulator 91 controls each of the plurality of air cylinders 82 such that all of the pressing forces Pa to Pe and PK to PT become the ideal pressing force Pt. As an example, the pressing force P of the brush bodies 32 may be uniformly adjusted for each of the brush groups J1, J3, and J4.

That is, for the brush bodies 32a to 32e included in the first brush group J1, the electro-pneumatic regulator 91 controls the air cylinders 82a to 82e such that the pressing forces Pa to Pe acting on the substrate W from each brush body 32 all become a first ideal pressing force Pt1. And for the brush bodies 32K to 32O included in the third brush group J3, the electro-pneumatic regulator 91 controls the air cylinders 82K to 82O such that each of the pressing forces PK to PO acting on the substrate W from each brush body 32 all becomes a second ideal pressing force Pt2. Air cylinders 82K to 82O independently adjust the height of the connecting members 83K to 83O connected to each of the brush bodies 32K to 32O.

And for the brush bodies 32P to 32T included in the fourth brush group J4, the electro-pneumatic regulator 91 controls the air cylinders 82P to 82T such that each of the pressing forces PP to PT acting on the substrate W from each brush body 32 all becomes a third ideal pressing force Pt3. The air cylinders 82P to 82T independently adjust the height of the connecting members 83P to 83T connected to each of the brush bodies 32P to 32T. In this way, even with a configuration that performs adjustment to uniformize the pressing force P acting on the substrate W from each brush body 32 for each of the brush groups J1, J3, and J4, a decrease in cleaning efficiency and the like due to the pressing force P of the brush bodies 32 becoming non-uniform can be avoided.

Here, the effects of the configuration of Embodiment 3 including the cleaning brush 10B will be described using FIG. 37 and the like. As an overview, in Embodiment 3, in Steps S10 and S13 and the like, each region of the substrate W is cleaned a plurality of times by using a plurality of brush bodies 32 composed of materials having different cleaning characteristics.

FIG. 37 shows the positional relationship between the substrate W and the brush bodies 32 when the cleaning brush 10B is brought into contact with the back surface of the substrate W. When the cleaning brush 10B is brought into contact with the back surface of the substrate W, the first brush group J1, the third brush group J3, and the fourth brush group J4 are arranged so as to align with each other in the circumferential direction Mf of the substrate W. The third brush group J3 is arranged at a position slightly separated from the first brush group J1 in the clockwise direction in the circumferential direction Mf. The fourth brush group J4 is arranged at a position slightly separated from the first brush group J1 in the counterclockwise direction in the circumferential direction Mf.

As an example, the brush body 32a of the first brush group J1, the brush body 32K of the third brush group J3, and the brush body 32P of the fourth brush group J4 are arranged so as to align in the circumferential direction Mf. Similarly, the brush body 32b, the brush body 32L, and the brush body 32Q are arranged in parallel in the circumferential direction Mf. The brush body 32c, the brush body 32M, and the brush body 32R are arranged in parallel in the circumferential direction Mf. The brush body 32d, the brush body 32N, and the brush body 32S are arranged in parallel in the circumferential direction Mf. The brush body 32e, the brush body 32O, and the brush body 32T are arranged in parallel in the circumferential direction Mf.

Since the three brush groups J1, J3, and J4 are arranged in parallel in the circumferential direction of the substrate W, the substrate W is cleaned a total of three times by each of the three brush groups J1, J3, and J4 by rotating the substrate W in a state where the cleaning brush 10B is in contact with the substrate W by the holding rotation part 3. That is, when the substrate W in a state where the cleaning brush 10B is in contact is rotated in the counterclockwise direction, each region of the substrate W is first cleaned by the third brush group J3, then cleaned by the first brush group J1, and finally cleaned by the fourth brush group J4.

The relationship between the regions of the substrate W and the brush bodies 32 that clean the regions will be described using FIG. 37. As shown in FIG. 37, predetermined regions on the substrate W are designated as regions B1 to B5. The regions B1 to B5 align in the radial direction of the substrate W. A region B1 is the region located closest to the inner side of the substrate W among regions B1 to B5. The region B5 is the region located closest to the outer side of the substrate W among the regions B1 to B5. In FIG. 37, the direction of rotating the substrate W (counterclockwise direction) is indicated by the reference sign Vf.

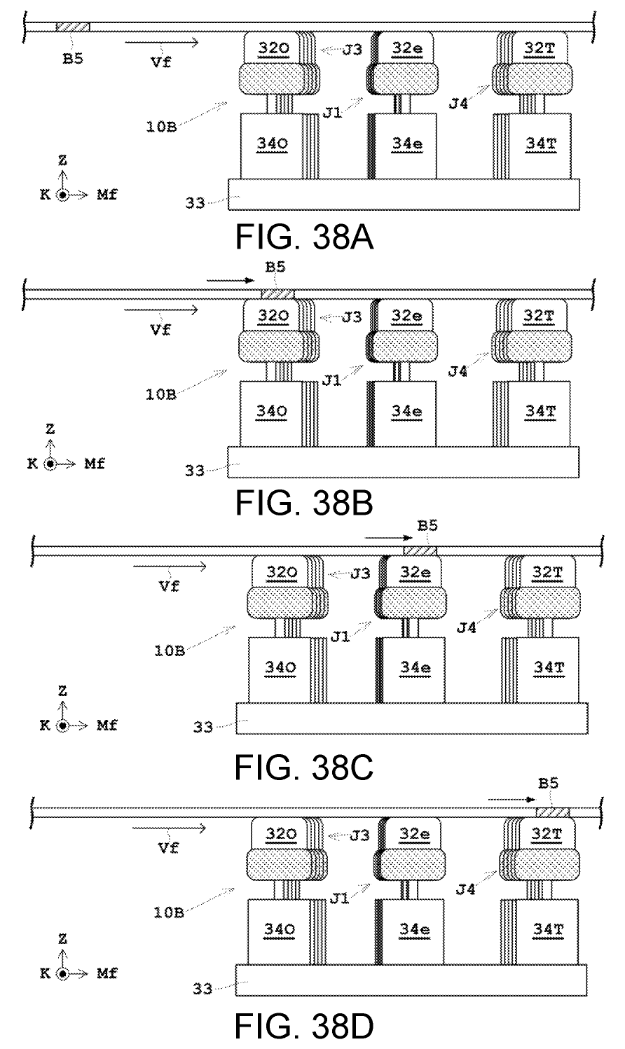

FIGS. 38A to 38D are side views showing the step in which the region B5 of the substrate W is cleaned by each brush body 32 when the substrate W is rotated in the direction indicated by the reference sign Vf. FIG. 38A is a side view when the substrate W and the brush body 32 shown in FIG. 37 are viewed from the direction indicated by the reference sign Ey. When the substrate W in a state where the cleaning brush 10B is in contact is rotated in the counterclockwise direction, as shown in FIG. 38B, the region B5 is first cleaned by the brush body 32O of the third brush group J3. The brush body 32O included in the third brush group J3 is configured by a polishing member having relatively high hardness (abrasive grain as an example). The abrasive grain configuring the brush body 32O polishes and cleans the main contaminants adhering to the region B5 in the initial stage of cleaning the region B5 on the back surface of the substrate W (polishing cleaning step).

After the region B5 is cleaned by the brush body 32O, it further rotates in the direction indicated by the reference sign Vf. Then, as shown in FIG. 38C, the region B5 is next cleaned by the brush body 32e of the first brush group J1. The brush body 32e included in the first brush group J1 is configured by a polishing member having lower hardness than the brush body 32O (a sponge made of PVA as an example). The brush body 32e removes most of the particles that could not be completely removed by the brush body 32O having relatively high hardness in the intermediate stage of cleaning the region B5 on the back surface of the substrate W (rough cleaning step).

After the region B5 is cleaned by the brush body 32e, it further rotates in the direction indicated by the reference sign Vf. Then, as shown in FIG. 38D, the region B5 is finally cleaned by the brush body 32T of the fourth brush group J4. The brush body 32T included in the fourth brush group J4 is configured by a polishing member having even lower hardness than the brush body 32e (a sponge made of RN as an example). The brush body 32T precisely removes fine particles that could not be completely removed by the brush body 32O and the brush body 32e in the final stage of cleaning the region B5 on the back surface of the substrate W (finish cleaning step).

Similarly, the regions B1 to B4 of the substrate W are also cleaned in order using the brush bodies 32 of the third brush group J3, the first brush group J1, and the fourth brush group J4. That is, when the substrate W in a state where the cleaning brush 10B is in contact is rotated in the counterclockwise direction, the region B1 is first cleaned by the brush body 32K of the third brush group J3, next cleaned by the brush body 32a of the first brush group J1, and finally cleaned by the brush body 32P of the fourth brush group J4. The region B2 is first cleaned by the brush body 32L, next cleaned by the brush body 32b, and finally cleaned by the brush body 32Q. The region B3 is first cleaned by the brush body 32M, next cleaned by the brush body 32c, and finally cleaned by the brush body 32R. The region B4 is first cleaned by the brush body 32N, next cleaned by the brush body 32d, and finally cleaned by the brush body 32S.

As described above, in Embodiment 3, cleaning is performed a plurality of times using three brush bodies 32 configured by materials each having different cleaning characteristics. By performing cleaning a plurality of times using brush bodies 32 each having different cleaning characteristics, it is possible to efficiently remove from major contaminants (as an example, contaminants having large particle size and high adhesiveness to the substrate W) to fine particles. Therefore, the cleaning efficiency of the substrate W by the cleaning brush 10B can be further improved.

The disclosure is not limited to the above embodiments, and may be modified and implemented as follows.

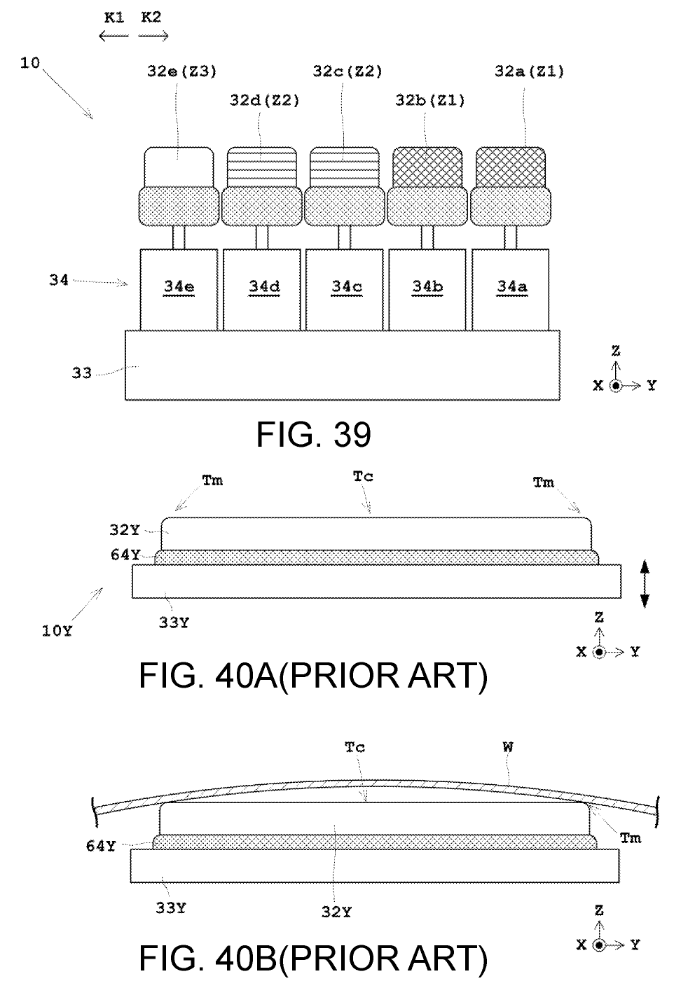

(1) In Embodiment 1 described above, the brush bodies 32a to 32e are not limited to a configuration in which all are formed of materials having the same cleaning characteristics. That is, a group of brush bodies 32 arranged in parallel in the radial direction of the substrate W may be formed of materials each having different cleaning characteristics. FIG. 39 shows a modification example in which the brush bodies 32a to 32e are formed of materials each having different cleaning characteristics.

In the modification example shown in FIG. 39, the brush bodies 32a and 32b arranged at positions close to the back center region Ce are formed of abrasive grain Z1, which is a relatively hard material. The brush body 32e arranged at a position far from the back center region Ce is formed of RN sponge Z3, which is a relatively soft material. The brush bodies 32c and 32d arranged at intermediate positions are formed of PVA sponge Z2. The PVA sponge Z2 is a material having hardness lower than the abrasive grain Z1 and higher than the RN sponge Z3.

As an example, in the case where many major contaminants are adhered to a part close to the back center region Ce of the substrate W, by forming the brush body 32 close to the back center region Ce with a material having high hardness, the substrate W in the part close to the back center region Ce may be suitably cleaned. On the other hand, in the case where many fine particles are adhered to a part close to the peripheral edge part Wg of the substrate W, by forming the brush body 32 close to the peripheral edge part Wg (the brush body 32 far from the back center region Ce) with a material having low hardness, the substrate W in the part close to the peripheral edge part Wg may also be suitably cleaned. In this way, by changing the constituent material of the brush body 32 according to each of the different contamination states for each region of the substrate W, the cleaning efficiency for the substrate W having different contamination states for each region can be improved.

(2) In each of the above-described examples, the configuration is not limited to cleaning the back outer region Cf of the substrate after cleaning the back center region Ce of the substrate W, and the back outer region Cf may be cleaned before the back center region Ce. That is, the steps of Steps S9 to S13 of cleaning the back outer region Cf using the back side cleaning mechanism 9 may be performed before the steps of Steps S2 to S6 of cleaning the back center region Ce using the back side cleaning mechanism 9. In this modification example as well, by performing the step (such as Step S4) of uniformly adjusting each of the pressing forces P acting on the substrate W from each of the brush bodies 32 each time the substrate W is moved relative to the cleaning brush 10, the cleaning efficiency of the substrate W can be improved while avoiding the occurrence of deformation or damage to the substrate.

(3) In each of the above-described examples, in Step S5 of cleaning the back center region Ce of the substrate W, the configuration in which the rotary drive part 35 rotates the cleaning brush 10 was shown as an example, but the configuration is not limited to this. That is, any configuration that rotates the cleaning brush 10 relative to the substrate W may be used, and as an example, the back center region Ce may be cleaned by rotating the substrate W around the vertical shaft AX1 in a state where the cleaning brush 10 is in contact with the back center region Ce.

(4) In each of the above-described examples, in Step S10 and Step S13 of cleaning the back outer region Cf of the substrate W, the configuration in which the substrate W is rotated around the vertical shaft AX1 was shown as an example, but the configuration is not limited to this. That is, any configuration that rotates the cleaning brush 10 relative to the substrate W may be used, and the back outer region Cf may be cleaned by rotationally moving the cleaning brush 10 along a circumferential trajectory around the vertical shaft AX1.

(5) In each of the above-described examples, the configuration of the cleaning brush 10 including the plurality of brush bodies 32 and the pressing force adjustment mechanism that uniformly adjusts each of the pressing forces P of the brush bodies 32 is not limited to the configuration arranged only in the back side cleaning mechanism 9. That is, the cleaning brush 10 may be arranged in the front surface cleaning mechanism 13. In this case, scrub cleaning may be performed on the front surface of the substrate W while uniformly adjusting each of the pressing forces P that each of the brush bodies 32 applies to the front surface of the substrate W.

(6) In each of the above-described examples, the shape of the brush body 32 in plan view is not limited to the circular shape as shown in FIG. 3 and the like. The shape of the brush body 32 in plan view may be, as an example, rectangular, polygonal, cross-shaped, or the like.

(7) In each of the above-described examples, the configuration in which the electro-pneumatic regulator 91 of the pressing force adjustment mechanism 15 controls each of the air cylinders 82 such that all of the pressing forces P of each of the brush bodies 32 become the ideal pressing force Pt was illustrated, but the configuration for uniformly adjusting each of the pressing forces P is not limited to this. As an example, when uniformly adjusting the five pressing forces Pa to Pe, any one of the pressing forces Pa to Pe may be selected as a reference pressing force Px, and each of the air cylinders 82 may be controlled such that each of the pressing forces Pa to Pe becomes the reference pressing force Px. As another example, each of the pressing forces Pa to Pe may be uniformly adjusted by feedback controlling each of the air cylinders 82 such that the pressing forces Pa to Pe are appropriately compared and the difference between them approaches zero.

What is claimed is:

1. A substrate processing device, comprising
a plurality of cleaning members arranged in parallel in a radial direction of a substrate and cleaning the substrate;
a support member supporting the plurality of cleaning members;
a rotary drive part causing the support member to relatively rotate with respect to the substrate;
a plurality of connecting members connecting each of the plurality of cleaning members and the support member and each being capable of moving up and down independently; and
a pressing force adjustment mechanism causing the plurality of connecting members to move up and down respectively such that each of pressing forces exerted on the substrate by each of the plurality of cleaning members becomes uniform.

2. The substrate processing device according to claim 1,
wherein the pressing force adjustment mechanism comprises:
an elevation drive part causing the connecting member to move up and down;
a pressure gauge measuring each of the pressing forces; and
an elevation drive control part causing each of the connecting members to move up and down to a height at which each of the pressing forces becomes uniform by controlling the elevation drive part according to a value of each of the pressing forces measured by the pressure gauge.

3. The substrate processing device according to claim 2,
wherein the pressure gauge is configured to re-measure each of the pressing forces after the elevation drive control part controls the elevation drive part, and
the pressing force adjustment mechanism causes the plurality of connecting members to move up and down respectively by feedback control such that each of the pressing forces exerted on the substrate by each of the plurality of cleaning members becomes uniform.

4. The substrate processing device according to claim 2,
wherein the elevation drive part is a plurality of air cylinders arranged to correspond to each of the plurality of connecting members, and
the elevation drive control part causes each of the connecting members to move up and down to a height at which each of the pressing forces becomes uniform by controlling an amount of gas supplied to each of the plurality of air cylinders.

5. The substrate processing device according to claim 1,
wherein the pressing force adjustment mechanism causes the plurality of connecting members to move up and down respectively such that each of the pressing forces becomes a predetermined ideal pressing force value.

6. The substrate processing device according to claim 1,
wherein the plurality of cleaning members are arranged in parallel so as to form a plurality of rows extending in the radial direction of the substrate, and
the plurality of cleaning members included in a predetermined row are arranged in a zigzag manner with respect to the plurality of cleaning members included in a row adjacent to the predetermined row.

7. The substrate processing device according to claim 1,
wherein the plurality of cleaning members are composed of materials each having different cleaning characteristics, and
the pressing force adjustment mechanism causes the plurality of connecting members to move up and down respectively such that each of the pressing forces exerted on the substrate by each of the plurality of cleaning members becomes uniform.

8. The substrate processing device according to claim 1,
wherein the plurality of cleaning members are arranged in parallel so as to form a plurality of brush groups each comprising two or more of the cleaning members arranged in parallel in the radial direction of the substrate,
each of the plurality of brush groups is arranged to align in a circumferential direction of the substrate,
the plurality of cleaning members included in the same brush group are all composed of materials having the same cleaning characteristics,
the plurality of cleaning members included in different brush groups are composed of materials having mutually different cleaning characteristics, and
the pressing force adjustment mechanism causes the plurality of connecting members to move up and down respectively such that each of the pressing forces exerted on the substrate by each of the plurality of cleaning members becomes uniform.

9. The substrate processing device according to claim 1,
wherein the plurality of cleaning members are arranged to form a plurality of brush groups each comprising two or more of the cleaning members arranged in parallel in the radial direction of the substrate,
each of the plurality of brush groups is arranged to align in a circumferential direction of the substrate,
the plurality of cleaning members included in the same brush group are all composed of materials having the same cleaning characteristics,
the plurality of cleaning members included in different brush groups are composed of materials having mutually different cleaning characteristics, and
the pressing force adjustment mechanism causes the plurality of connecting members to move up and down respectively such that each of the pressing forces exerted on the substrate by each of the plurality of cleaning members included in the same brush group becomes uniform.
